(19) United States
(12) Patent Application Publication
(10) Pub. No.: US 2022/0301912 A1
(43) Pub. Date: Sep. 22, 2022

(54) SUBSTRATE TRANSPORT DEVICE AND SUBSTRATE TRANSPORT METHOD

(71) Applicant: SCREEN HOLDINGS CO., LTD., Kyoto (JP)

(72) Inventor: Joji KUWAHARA, Kyoto-shi (JP)

(21) Appl. No.: 17/697,054

(22) Filed: Mar. 17, 2022

(30) Foreign Application Priority Data
Mar. 19, 2021 (JP) 2021-046272

(51) Int. Cl. H01L 21/68; H01L 21/687; G03F 7/20

(52) U.S. Cl. CPC H01L 21/681; H01L 21/68707; G03F 7/7075; G03F 7/70775; H01L 21/6838

(57) ABSTRACT

A substrate transport device includes a hand configured to be capable of holding a substrate, a plurality of reflective photo detectors provided at the hand, a portion position calculator and a substrate position determiner. The plurality of reflective photo detectors respectively emit light toward an outer periphery of the substrate arranged on the hand, respectively receive light reflected from the substrate using linear light transmission surfaces and output signals representing light receiving amounts. A portion position calculator calculates respective positions of a plurality of portions of an outer peripheral end of the substrate in the hand based on output signals of the plurality of reflective photo detectors. A substrate position determiner determines the position of the substrate with respect to the hand based on the calculated positions of the plurality of portions of the substrate.

### BACKGROUND

### Technical Field

The present invention relates to a substrate transport device and a substrate transport method, of transporting a substrate.

### Description of Related Art

A substrate processing apparatus is used to perform various processes on various substrates such as a substrate for an FPD (Flat Panel Display) that is used for a liquid crystal display device, an organic EL (Electro Luminescence) display device or the like, a semiconductor substrate, a substrate for an optical disc, a substrate for a magnetic disc, a substrate for a magneto-optical disc, a substrate for a photomask, a ceramic substrate or a substrate for a solar cell.

In a substrate processing apparatus, processing is performed on one substrate successively by a plurality of processing units, for example. Therefore, in the substrate processing apparatus, a substrate transport device that transports the substrate among the plurality of processing units is provided. In such a substrate transport device, the substrate is transported while being held by a holder. In a case in which the substrate is held at a deviating position with respect to the holder, the substrate cannot be transported with high accuracy. As such, the configuration for determining the position of the substrate with respect to the holder has been suggested.

For example, in a substrate transport device described in JP 2018-133415 A, a substrate to be processed is held by a holder (hand) and is transported by movement of the holder. Specifically, when the substrate is transported from a first position to a second position, the substrate is received by the holder at the first position, and then the holder holding the substrate moves to a predetermined third position (advancing retreating initial position). During this movement, first to fifth portions of the outer peripheral end of the substrate held by the holder are detected. Based on the detection, the positions of the first to fifth portions in the holder are respectively calculated. The position of the substrate in the holder is determined based on the calculated positions of the first to fifth portions. Further, in a substrate transport device described in JP 2012-182393 A, with a holder (folk) holding a substrate located at a predetermined position, the positions of four portions of the outer peripheral end of the substrate held by the holder are measured. The position of the substrate in the holder is determined based on the result of measurement.

### SUMMARY

In a case in which a period of time required for transporting a substrate by a substrate transport device can be shortened, the throughput of substrate processing in a substrate processing apparatus is improved. Therefore, it is desirable that a period of time required for determination of the position of the substrate by the substrate transport device is reduced.

An object of the present invention is to provide a substrate transport device and a substrate transport method that enable a reduction in period of time required for determination of a position of a substrate.

(1) A substrate transport device according to one aspect of the present invention transports a substrate and includes a holder configured to be capable of holding the substrate, a plurality of reflective photo detectors that have linear light receiving surfaces, are provided at the holder, respectively emit light toward an outer periphery of the substrate arranged on the holder, respectively receive light reflected from the substrate using the light receiving surfaces and output signals representing light receiving amounts, a portion position calculator that calculates respective positions of a plurality of portions of an outer peripheral end of the substrate in the holder in regard to the substrate arranged on the holder based on output signals of the plurality of reflective photo detectors, and a position determiner that determines a position of the substrate with respect to the holder based on positions of the plurality of portions of the substrate calculated by the portion position calculator.

In the substrate transport device, light is emitted from the plurality of reflective photo detectors provided at the holder to the outer periphery of the substrate. In this case, an amount of light reflected from the outer periphery of the substrate changes in accordance with the position of the outer peripheral end of the substrate in the direction in which the linear light receiving surfaces extend. Therefore, with the light receiving amounts indicated by the output signals of the plurality of first reflective photo detectors, the positions of the plurality of portions of the outer peripheral end of the substrate in the direction in which the linear receiving surfaces of the plurality of reflective photo detectors extend can be calculated. Thus, the position of the substrate with respect to the holder can be determined at a point in time at which the substrate is arranged on the holder. As a result, a period of time required for determination of the position of the substrate during transportation of the substrate can be reduced.

(2) The plurality of reflective photo detectors may respectively have strip-shaped detection regions extending upwardly from the light receiving surfaces, and the plurality of portions may be intersections between the detection regions of the plurality of reflective photo detectors and the outer peripheral end of the substrate arranged on the holder in a plan view. In this case, the position of the substrate can be determined based on the calculated positions of the plurality of portions of the substrate.

(3) The plurality of reflective photo detectors may include first and second reflective photo detectors provided at the holder such that the light receiving surfaces do not overlap with each other in one direction. In this case, the positions of the plurality of portions of the substrate can be calculated with high accuracy based on output signals of the first and second reflective photo detectors and the positional relationship between the first and second reflective photo detectors.

(4) The substrate transport device may further include a storage that stores light amount position information representing a predetermined relationship between an amount of light received by the plurality of reflective photo detectors and positions of the plurality of portions of the substrate in the holder, wherein the portion position calculator may calculate respective positions of the plurality of portions of the substrate in the holder based on the light amount position information stored in the storage in addition to output signals of the plurality of reflective photo detectors. In this case, the positions of the plurality of portions of the outer peripheral end of the substrate can be calculated with high accuracy based on the light amount position information.

(5) The substrate transport device may further include a light receiving amount measurer that is provided at the holder, emits light toward an inner portion located inwardly of the outer periphery of the substrate, receives light reflected from the substrate and outputs a signal indicating a light receiving amount, and a light amount position information generator that generates light amount position information representing a relationship between an amount of light received by the plurality of reflective photo detectors and positions of the plurality of portions of the substrate in the holder based on an output signal of the light receiving amount measurer, wherein the portion position calculator may calculate respective positions of the plurality of portions of the substrate in the holder based on the light amount position information generated by the light amount position information generator in addition to output signals of the plurality of reflective photo detectors.

In this case, even in a case in which the reflectance of light with respect to the substrate is not known, the light amount position information is generated based on the output signal of the receiving light amount measurer. Thus, the positions of the plurality of portions of the outer peripheral end of the substrate can be calculated with high accuracy based on the generated light amount position information.

(6) The holder may further have a plurality of suction portions that hold a lower surface of the substrate by suction, and a distance between the light receiving amount measurer and one suction portion out of the plurality of suction portions may be smaller than a distance between each of the plurality of reflective photo detectors and the one suction portion.

In this case, the light receiving amount measurer is located close to one suction portion as compared to the plurality of reflective photo detectors. Therefore, even in a case in which the substrate is deformed such as being warped, the height of an inner portion of the substrate that receives light from the light receiving amount measurer is kept substantially constant by the one suction portion. Therefore, variations in condition for generating the light amount position information are reduced. As a result, the positions of the plurality of portions of the outer peripheral end of the substrate can be calculated with higher accuracy based on the appropriately generated light amount position information.

(7) The substrate transport device may further include a height detector that detects heights of the plurality of portions of the substrate in the holder, and a corrector that corrects respective positions of the plurality of portions of the substrate calculated by the portion position calculator based on heights of the plurality of portions of the substrate detected by the height detector, wherein the position determiner may determine a position of the substrate with respect to the holder based on positions of the plurality of portions of the substrate after the positions are corrected by the corrector.

An amount of light that returns to the reflective photo detector by being emitted from the reflective photo detector and reflected from the substrate changes depending on the distance between the reflective photo detector and the substrate. With the above-mentioned configuration, the heights of the plurality of portions of the outer peripheral end of the substrate are detected, and a result of calculation of the positions of the plurality of portions of the outer peripheral end of the substrate is corrected based on the detected heights. Therefore, the positions of the plurality of portions of the outer peripheral end of the substrate can be acquired with higher accuracy.

(8) The substrate transport device may further include a photo detector controller that controls the plurality of reflective photo detectors, wherein the light detector controller may be configured to be workable in a first control mode in which the light detector controller controls the plurality of reflective photo detectors with the substrate held by the holder, and a second control mode in which the light detector controller controls the plurality of reflective photo detectors with the substrate not held by the holder and the holder arranged at a position below the substrate supported by a supporter.

In this case, even in a case in which the substrate is held by the holder or the holder is arranged below the substrate supported by the supporter, the position of the substrate in the holder can be determined.

(9) The substrate transport device may further include a mover that moves the holder, and a movement controller that controls the mover based on a result of determination by the position determiner such that the substrate held by the holder is transported from a predetermined first position to a predetermined second position.

In this case, the substrate held by the holder can be transported from the predetermined first position to the predetermined second position with high accuracy based on a result of determination made by the position determiner.

(10) A substrate transport method according to another aspect of the present invention of transporting a substrate includes arranging a substrate on a holder configured to be capable of holding the substrate, using a plurality of reflective photo detectors that have the linear light receiving surfaces and are provided at the holder, emitting light toward an outer periphery of the substrate arranged on the holder, receiving light reflected from the substrate and outputting signals respectively representing light receiving amounts from the plurality of reflective photo detectors, calculating respective positions of a plurality of portions of an outer peripheral end of the substrate in the holder in regard to the substrate arranged on the holder based on output signals of the plurality of reflective photo detectors, and determining a position of the substrate with respect to the holder based on positions of the plurality of portions of the substrate calculated in the calculating.

With the substrate transport method, the plurality of reflective photo detectors provided at the holder respectively emit light to the outer periphery of the substrate. In this case, an amount of light reflected from the outer periphery of the substrate changes in accordance with the position of the outer peripheral end of the substrate in the direction in which the linear light receiving surfaces extend. Therefore, with the light receiving amounts indicated by the output signals of the plurality of first reflective photo detectors, the positions of the plurality of portions of the outer peripheral end of the substrate in the direction in which the linear receiving surfaces of the plurality of reflective photo detectors extend can be calculated. Thus, the position of the substrate with respect to the holder can be determined at a point in time at which the substrate is arranged on the holder. As a result, a period of time required for determination of the position of the substrate during transportation of the substrate can be reduced.

(11) The plurality of reflective photo detectors may respectively have strip-shaped detection regions extending upwardly from the holder, and the plurality of portions may be intersections between detection regions of the plurality of reflective photo detectors and the outer peripheral end of the substrate arranged on the holder in a plan view. In this case, the position of the substrate can be determined based on the calculated positions of the plurality of portions of the substrate.

(12) The plurality of reflective photo detectors may include first and second reflective photo detectors provided at the holder such that the light receiving surfaces do not overlap with each other in one direction. In this case, the positions of the plurality of portions of the substrate can be calculated with high accuracy based on output signals of the first and second reflective photo detectors and the positional relationship between the first and second reflective photo detectors.

(13) The substrate transport method may further include storing light amount position information representing a predetermined relationship between an amount of light received by the plurality of reflective photo detectors and positions of the plurality of portions of the substrate in the holder, wherein the calculating may include calculating respective positions of the plurality of portions of the substrate in the holder based on the light amount position information stored in the storing in addition to output signals of the plurality of reflective photo detectors. In this case, the positions of the plurality of portions of the outer peripheral end of the substrate can be calculated with high accuracy based on the light amount position information.

(14) The substrate transport method may further include causing a light receiving amount measurer to output a signal indicating a light receiving amount by emitting light toward an inner portion located inwardly of the outer periphery of the substrate arranged on the holder using the light receiving amount measurer provided at the holder and receiving light reflected from the substrate and generating light amount position information representing a relationship between an amount of light received by the plurality of reflective photo detectors and positions of the plurality of portions of the substrate in the holder based on an output signal of the light receiving amount measurer, wherein the calculating may include calculating respective positions of the plurality of portions of the substrate in the holder based on the light amount position information generated in the generating in addition to output signals of the plurality of reflective photo detectors.

In this case, even in a case in which the reflectance of light with respect to the substrate is not known, the light amount position information is generated based on the output signal of the receiving light amount measurer. Thus, the positions of the plurality of portions of the outer peripheral end of the substrate can be calculated with high accuracy based on the generated light amount position information.

(15) The arranging a substrate on a holder may include holding a lower surface of the substrate by suction using a plurality of suction portions of the holder, and a distance between the light receiving amount measurer and one suction portion out of the plurality of suction portions may be smaller than a distance between each of the plurality of reflective photo detectors and the one suction portion.

In this case, the light receiving amount measurer is located close to one suction portion as compared to the plurality of reflective photo detectors. Therefore, even in a case in which the substrate is deformed such as being warped, the height of an inner portion of the substrate that receives light from the light receiving amount measurer is kept substantially constant by the one suction portion. Therefore, variations in condition for generating the light amount position information are reduced. As a result, the positions of the plurality of portions of the outer peripheral end of the substrate can be calculated with higher accuracy based on the appropriately generated light amount position information.

(16) The substrate transport method may further include detecting heights of the plurality of portions of the substrate in the holder, and correcting respective positions of the plurality of portions of the substrate calculated in the calculating based on heights of the plurality of portions of the substrate detected in the detecting heights, wherein the determining a position of a substrate may include determining a position of the substrate with respect to the holder based on positions of the plurality of portions of the substrate after the positions are corrected in the correcting.

An amount of light that returns to the reflective photo detector by being emitted from the reflective photo detector and reflected from the substrate changes depending on the distance between the reflective photo detector and the substrate. With the above-mentioned configuration, the heights of the plurality of portions of the outer peripheral end of the substrate are detected, and a result of calculation of the positions of the plurality of portions of the outer peripheral end of the substrate is corrected based on the detected heights. Therefore, the positions of the plurality of portions of the outer peripheral end of the substrate can be acquired with higher accuracy.

(17) The causing a light receiving amount measurer to output a signal indicating a light receiving amount may include emitting light toward the outer periphery of the substrate held by the holder and emitting light toward the outer periphery of the substrate with the substrate not held by the holder and the holder arranged at a position below the substrate supported by a supporter.

In this case, even in a case in which the substrate is held by the holder or the holder is arranged below the substrate supported by the supporter, the position of the substrate in the holder can be determined.

(18) The substrate transport method may further include moving the holder such that the substrate held by the holder is transported from a predetermined first position to a predetermined second position based on a result of determination in the determining a position of a substrate.

In this case, the substrate held by the holder can be transported from the predetermined first position to the predetermined second position with high accuracy based on a result of determination made in the step of determining the position of the substrate.

Other features, elements, characteristics, and advantages of the present disclosure will become more apparent from the following description of preferred embodiments of the present disclosure with reference to the attached drawings.

### BRIEF DESCRIPTION OF THE DRAWING

FIG. 1 is a plan view of a substrate transport device according to a first embodiment;

FIG. 2 is a side view of the substrate transport device of FIG. 1;

FIG. 3 is a front view of the substrate transport device of FIG. 1;

FIG. 4 is a partially enlarged perspective view of a hand for explaining the details of reflective photo detectors of FIG. 1;

FIG. 5 is a diagram showing one example of light amount position information;

FIG. 6 is a block diagram showing the configuration of a control system of the substrate transport device according to the first embodiment;

FIG. 7 is a plan view showing one example of an XY coordinate system defined in a hand;

FIG. 8 is a plan view showing the positional relationship between a substrate on a hand and one imaginary circle in a case in which at least one of a plurality of amounts of deviation exceeds a threshold value;

FIG. 9 is a plan view showing the positional relationship between the substrate on the hand and another imaginary circle in a case in which at least one of the plurality of amounts of deviation exceeds the threshold value;

FIG. 10 is a plan view showing the positional relationship between the substrate on the hand and yet another imaginary circle in a case in which at least one of the plurality of amounts of deviation exceeds the threshold value;

FIG. 11 is a plan view showing the positional relationship between the substrate on the hand and yet another imaginary circle in a case in which at least one of the plurality of amounts of deviation exceeds the threshold value;

FIG. 12 is a block diagram showing the functional configuration of a transport controller according to the first embodiment;

FIG. 13 is a flowchart showing the basic work for transporting the substrate performed by the substrate transport device according to the first embodiment:

FIG. 14 is a flowchart showing the basic work for transporting the substrate performed by the substrate transport device according to the first embodiment;

FIG. 15 is a plan view of a substrate transport device according to a second embodiment;

FIG. 16 is a block diagram showing the configuration of a control system of the substrate transport device according to the second embodiment;

FIG. 17 is a block diagram showing the functional configuration of the transport controller according to the second embodiment;

FIG. 18 is a flowchart showing part of the basic work for transporting the substrate performed by the substrate transport device according to the second embodiment;

FIG. 19 is a plan view of a substrate transport device according to a third embodiment;

FIG. 20 is a block diagram showing the configuration of a control system of the substrate transport device according to the third embodiment;

FIG. 21 is a block diagram showing the functional configuration of the transport controller according to the third embodiment;

FIG. 22 is a flowchart showing part of the basic work for transporting the substrate performed by the substrate transport device according to the third embodiment;

FIG. 23 is a diagram for explaining one example of work of a substrate transport device when a transport controller according to a fourth embodiment is in a second control mode;

FIG. 24 is a diagram for explaining one example of work of the substrate transport device when the transport controller according to the fourth embodiment is in the second control mode;

FIG. 25 is a diagram for explaining one example of work of the substrate transport device when the transport controller according to the fourth embodiment is in the second control mode;

FIG. 26 is a diagram for explaining one example of work of the substrate transport device when the transport controller according to the fourth embodiment is in the second control mode;

FIG. 27 is a diagram for explaining one example of work of the substrate transport device when the transport controller according to the fourth embodiment is in the second control mode;

FIG. 28 is a flowchart showing the work for adjusting a position of the hand in a second working mode performed by the substrate transport device according to the fourth embodiment;

FIG. 29 is a flowchart showing the work for adjusting a position of the hand in the second working mode performed by the substrate transport device according to the fourth embodiment; and

FIG. 30 is a schematic block diagram showing the entire configuration of a substrate processing apparatus including the substrate transport device according to any one of the first to fourth embodiments.

### DETAILED DESCRIPTION

A substrate transport device and a substrate transport method according to one embodiment of the present invention will be described below with reference to the drawings. In the following description, a substrate refers to a substrate for an FPD (Flat Panel Display) that is used for a liquid crystal display device, an organic EL (Electro Luminescence) display device or the like, a semiconductor substrate, a substrate for an optical disc, a substrate for a magnetic disc, a substrate for a magneto-optical disc, a substrate for a photomask, a ceramic substrate, a substrate for a solar cells or the like. Further, as for a substrate used in the below-mentioned embodiments, at least part of the substrate has a circular outer peripheral end. Specifically, in a substrate, a notch for positioning is formed, and the outer peripheral end except for the notch is circular. In a substrate, an orientation flat may be formed instead of a notch.

### 1. First Embodiment

### [1] Configuration of Substrate Transport Device According to First Embodiment

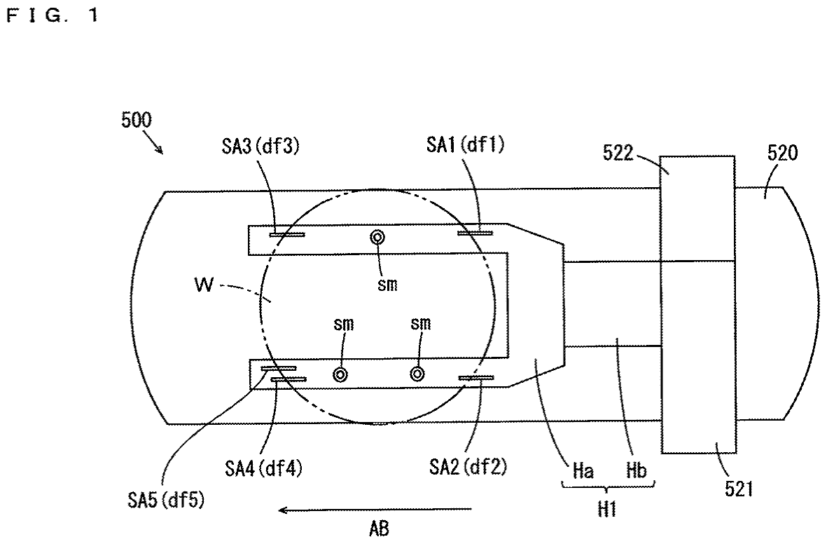

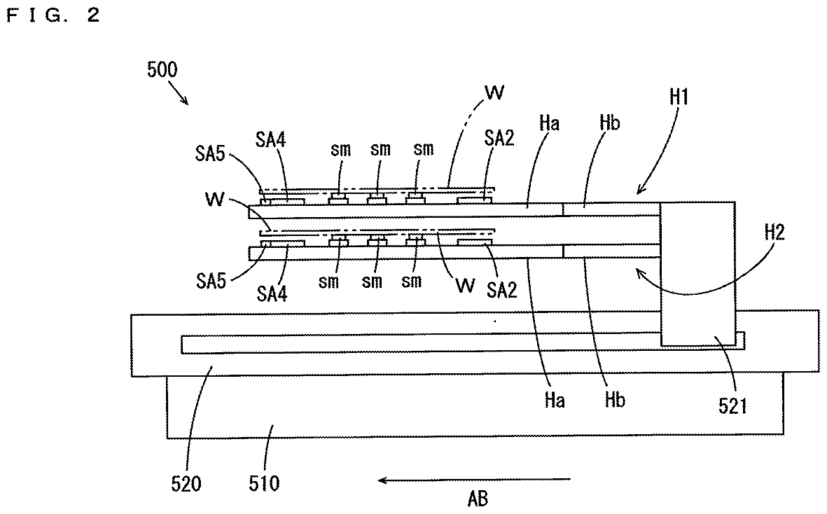

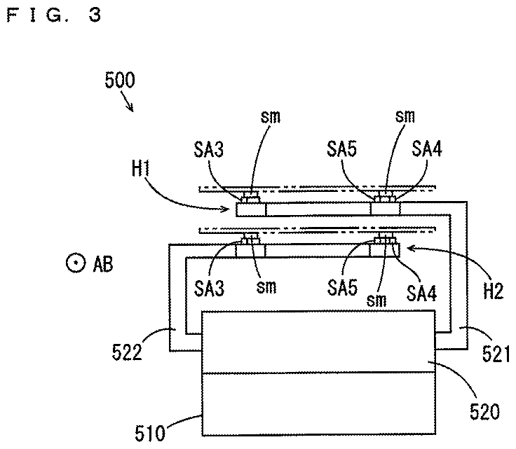

FIG. 1 is a plan view of a substrate transport device according to a first embodiment, FIG. 2 is a side view of the substrate transport device 500 of FIG. 1 and FIG. 3 is a front view of the substrate transport device 500 of FIG. 1. The substrate transport device 500 shown in each of FIGS. 1 to 3 includes a movement member 510 (FIGS. 2 and 3), a rotation member 520, two hands H1, H2 and a plurality of reflective photo detectors (reflective photo sensors) SA1, SA2, SA3, SA4, SA5 (FIG. 1). In the present embodiment, the five reflective photo detectors SA1 to SA5 are provided in each of the two hands H1, H2. The movement member 510 is configured to be movable in a horizontal direction along a guide rail (not shown).

The substantially cuboid-shaped rotation member 520 is provided on the movement member 510 to be rotatable about an axis extending in a vertical direction. Support members 521, 522 are provided at the rotation member 520. The support members 521, 522 support the hands H1, H2, respectively. The hands H1, H2 can advance and retreat in a longitudinal direction of the rotation member 520 while being respectively supported by the support members 521, 522. In the present embodiment, the hand H2 is located above the upper surface of the rotation member 520, and the hand H1 is located above the hand H2. In the following description, as indicated by the arrows in FIGS. 1 to 3, the direction in which the hands H1, H2 can advance and retreat with respect to the rotation member 520 is referred to as an advancing retreating direction AB. In the present embodiment, the direction in which the arrows in FIGS. 1 to 3 are directed is forward, and its opposite direction is rearward.

Each of the hands H1, H2 is constituted by a guide portion Ha and an arm portion Hb. As shown in FIG. 1, the guide portion Ha has a substantially planar U-shape, and the arm portion Hb has a rectangular planar shape extending in one direction. The guide portion Ha is provided to branch into two from one end of the arm portion Hb.

On the upper surface of the guide portion Ha, a plurality (three in the present example) of suction portions sm are respectively provided in a plurality (three in the present example) of portions that are spaced apart from one another. Each suction portion sm is connected to a suction system (not shown). A substrate W is placed on the plurality of suction portions sm. In this state, the lower surface of the substrate W placed on the plurality of suction portions sm is sucked by the suction system through the plurality of suction portions sm. In each of FIGS. 1 to 3, the substrates W being held by suction by the hands H1, H2 that have ideal relationship with each other are indicated by the two-dots and dash lines.

The reflective photo detectors SA1 to SA5 basically have the common configuration. The reflective photo detectors SA1 to SA5 are distributed on the guide portion Ha such that part of each reflective photo detector overlaps with the outer peripheral end of the substrate W held by each of the hands H1, H2.

More specifically, as shown in FIG. 1, the reflective photo detectors SA1 to SA4 are arranged to overlap with the outer peripheral end of the substrate W at angular intervals of substantially 90° with respect to the center of the substrate W held by each of the hands H1, H2. On the other hand, the reflective photo detector SA5 is arranged in the vicinity of the reflective photo detector SA4. The distance between the reflective photo detectors SA4, SA5 is smaller than the diameter of the substrate W and larger than the length of a notch in the circumferential direction of the substrate W. The diameter of the substrate W according to the present embodiment is 300 mm, for example, and the length of the notch of the substrate W in the circumferential direction is 2.73 mm, for example. The height positions of the upper end portions of the plurality of reflective photo detectors SA1 to SA5 attached to each of the hands H1, H2 is lower than the height positions of the upper end portions of the plurality of suction portions sm attached to each of the hands H1, H2. Therefore, with the substrate W held by each of the hands H1, H2, the upper end portions of the reflective photo detectors SA1 to SA5 provided at the hand are spaced apart from the lower surface of the substrate W.

Each of the reflective photo detectors SA1 to SA5 emits linear light toward a detection region and receives return light from the detection region, and outputs a signal corresponding to a light receiving amount. In the present embodiment, each of the reflective photo detectors SA1 to SA5 is a so-called fiber sensor and is mainly constituted by a main body, an optical fiber and a fiber unit. The main body includes a light source and a light receiving element. The fiber unit includes one or a plurality of optical systems (lenses, etc.) and has an emission surface that emits light and a light receiving surface that receives light. The optical fiber connects the main body and the fiber unit to each other.

In the fiber sensor, light generated by the light source of the main body is guided to the fiber unit through the optical fiber. In the fiber unit, the light guided through the optical fiber is shaped into linear light through the optical system and emitted from the emission surface to the detection region. Light reflected from the detection region is incident on the light receiving surface as return light and guided to the light receiving element of the main body through the optical system and the optical fiber. The light receiving element outputs a signal corresponding to a light receiving amount by receiving the light guided from the optical fiber.

In this manner, in a case in which each of the reflective photo detectors SA1 to SA5 is constituted by a fiber sensor, only fiber unit is attached to the guide portion Ha of each of the hands H1, H2. Further, the main body is attached to a member different from the arm portion Hb or the hands H1, H2. Then, the fiber unit and the main body are connected to each other by the optical fiber. Therefore, in each of FIGS. 1 to 3, each of the reflective photo detectors SA1 to SA5 shown on each of the hands H1, H2 is the fiber unit of the fiber sensor. Each of the reflective photo detectors SA1 to SA5 may have the configuration in which the light source, the light receiving element and the optical system are contained in one casing. In this case, the emission surface and the light receiving surface are integrally provided in the one casing.

The reflective photo detectors SA1 to SA5 are used to calculate the positions of a plurality of portions of the outer peripheral end of the substrate W in each of the hands H1, H2 with the substrate W held on the each of hands H1, H2. A method of calculating the positions of the plurality of portions of the outer peripheral end of the substrate W using the reflective photo detectors SA4, SA5 which are representing the reflective photo detectors SA1 to SA5 will be described.

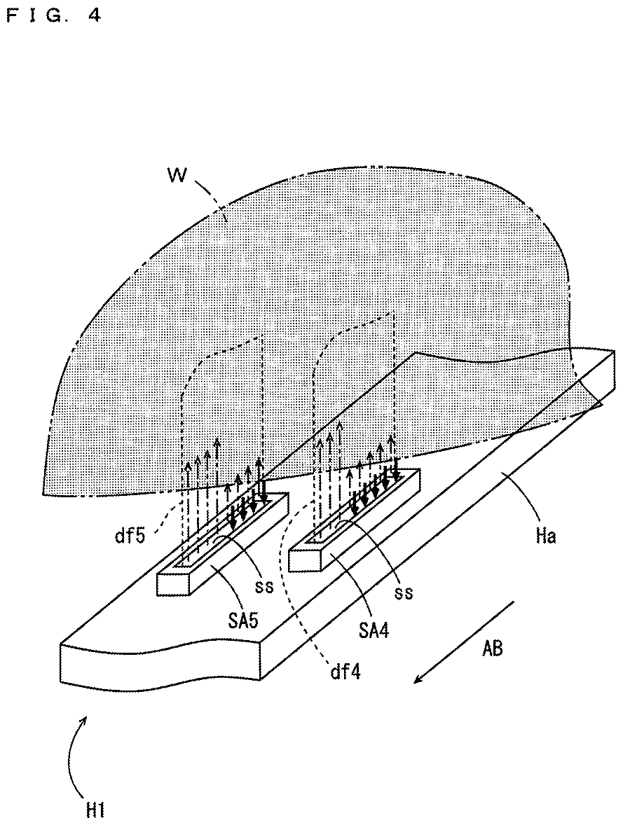

FIG. 4 is a partially enlarged perspective view of the hand H1 for explaining the details of the reflective photo detectors SA4, SA5 of FIG. 1. As shown in FIG. 4, each of the reflective photo detectors SA4, SA5 extends in one direction and has the light transmission surface ss directed upwardly, and is attached to the upper surface of the guide portion Ha such that the direction in which the light transmission surface ss extends is in parallel with the advancing retreating direction AB. The light transmission surface ss functions as the above-mentioned emission surface and the above-mentioned light receiving surface. In this state, the reflective photo detectors SA4, SA5 respectively have strip-shaped detection regions df4, df5 that extend upwardly from the light transmission surfaces ss.

In the hand H1 according to the present embodiment, the substrate W is held on the hand H1 by being sucked by the plurality of suction portions sm, so that part of the light transmission surface ss of each of the reflective photo detectors SA4, SA5 is opposite to the outer periphery of the substrate W while being spaced apart from the outer periphery of the substrate W by a predetermined distance. In FIG. 4, the substrate W held by the hand H1 is indicated by the dotted pattern. In this state, as indicated by the one-dot and dash arrows in FIG. 4, linear light is emitted upwardly from the light transmission surfaces ss of the reflective photo detectors SA4, SA5.

In this case, the light emitted from the portion of each light transmission surface ss opposite to the substrate W is reflected from the lower surface of the substrate W and is incident on the light transmission surface ss as indicated by the thick solid arrows in FIG. 4. On the other hand, the light emitted from the portion of each light transmission surface ss not opposite to the substrate W passes through the side of the substrate W. Therefore, light is not incident on the portion of each light transmission surface ss not opposite to the substrate W.

Here, suppose that the positions of the reflective photo detectors SA4, SA5 in the hand H1 are known, and the general positional relationship between each of the reflective photo detectors SA4, SA5 and the substrate W in the advancing retreating direction AB is known. In this case, based on output signals of the reflective photo detectors SA4, SA5, the positions of the portions of the outer peripheral end of the substrate W located in the detection regions df4, df5 in the advancing retreating direction AB in the hand H1 can be calculated. The general positional relationship between each of the reflective photo detectors SA4, SA5 and the substrate W represents whether each of the reflective photo detectors SA4, SA5 is located at a position farther forward or rearward than the center of the substrate W in the advancing retreating direction AB with the substrate W held by the hand H1, for example. Further, the above-mentioned portion of the outer peripheral end of the substrate W located in each of the detection regions df4, df5 means the intersection between each of the detection regions df4, df5 of the reflective photo detectors SA4, SA5 and the outer peripheral end of the substrate W held on the hand H1 in a plan view.

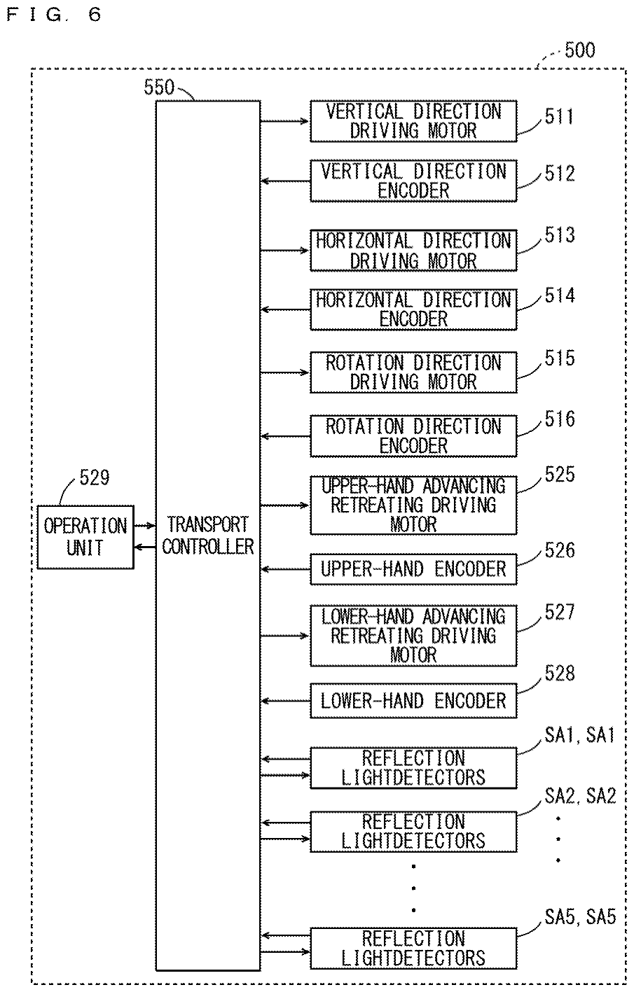

Meanwhile, the reflectance of the light emitted from the light transmission surface ss and reflected from the lower surface of the substrate W differs depending on the type of the substrate W. As such, in the present embodiment, in regard to each of the reflective photo detectors SA1 to SA5, the light amount position information representing the predetermined relationship between an amount of light received by the reflective photo detector and the position of the outer peripheral end of the substrate W irradiated with the light is used. The light amount position information is stored in a transport controller 550 (FIG. 6), described below.

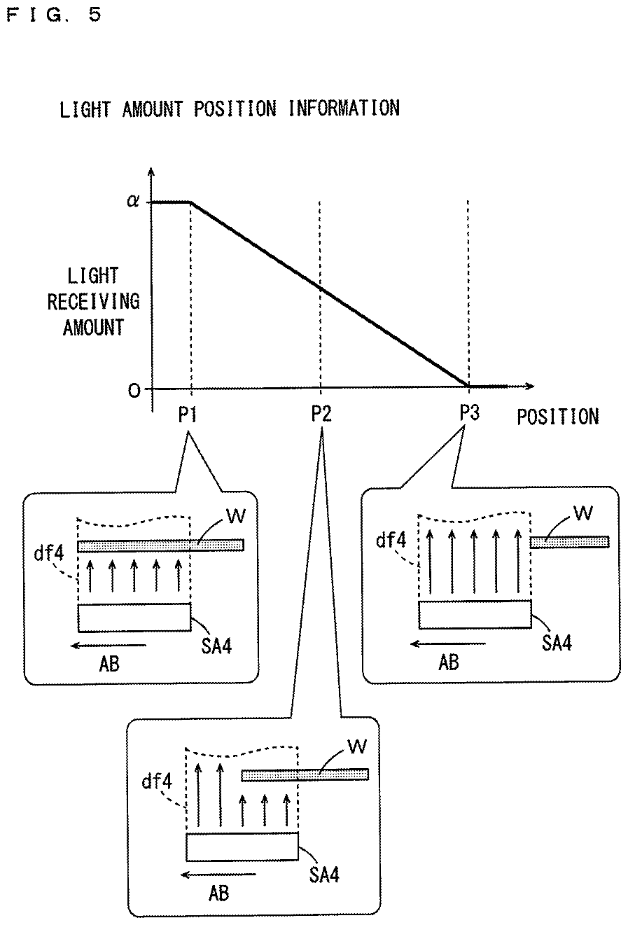

FIG. 5 is a diagram showing one example of the light amount position information. The light amount position information of FIG. 5 represents the relationship between an amount of light received by the reflective photo detector SA4 of FIG. 4 and the position of the outer peripheral end of the substrate W detected by the reflective photo detector SA4. In FIG. 5, the light amount position information corresponding to the reflective photo detector SA4 is represented by a graph. In the graph of FIG. 5, the ordinate indicates an amount of light received by the reflective photo detector SA4, and the abscissa indicates a position of the outer peripheral end of the substrate W in the advancing retreating direction AB in the hand H1. A light receiving amount indicated by a in the ordinate is a light receiving amount in a case in which all of the light that is emitted from the reflective photo detector SA4 and reflected from the substrate W returns (hereinafter referred to as a maximum light receiving amount), for example, and is defined based on the reflectance of the substrate W.

As shown in the graph of FIG. 5 and the balloon corresponding to the position P1, in a case in which a portion of the substrate W located above the reflective photo detector SA4 overlaps with the entire detection region df4, the maximum light receiving amount a is maintained in regard to the light receiving amount. On the other hand, as shown in the graph of FIG. 5 and the balloon corresponding to the position P2, in a case in which the portion of the substrate W located above the reflective photo detector SA4 overlaps with part of the detection region df4 (a rear half portion), the light receiving amount is lower than the maximum light receiving amount a. On the other hand, as shown in the graph of FIG. 5 and the balloon corresponding to the position P3, in a case in which the portion of the substrate W located above the reflective photo detector SA4 does not overlap with the detection region df4, the light receiving amount is 0.

Thus, with the light amount position information of FIG. 5, when one portion of the outer peripheral end of the substrate W is located in the detection region df4 of the reflective photo detector SA4, the position in the hand H1 in regard to the one portion of the outer peripheral end of the substrate W can be calculated. The light position detection information of FIG. 5 can be generated by experiments or simulation, for example.

With the above-mentioned configuration, at a point in time at which the substrate W is held by each of the hands H1, H2, it is possible to calculate the positions of the plurality of portions of the outer peripheral end of the substrate W in the hand can be calculated by the plurality of reflective photo detectors SA1 to SA5 without moving the hand.

In each of the hands H1, H2, a reference position at which the center of the held substrate W is to be located (hereinafter referred to as a reference position) is predetermined. The reference position in each of the hands H1, H2 is the center position among the three suction portions sm, for example.

In a case in which the positions of five portions of the outer peripheral end of the substrate W held by each of the hands H1, H2 can be calculated, the position of the substrate W in the hand can be determined. Thus, how much the center of the substrate W actually held by each of the hands H1, H2 deviates from the reference position can be calculated.

### [2] Configuration of Control System of Substrate Transport Device 500

FIG. 6 is a block diagram showing the configuration of a control system of the substrate transport device 500 according to the first embodiment. As shown in FIG. 6, the substrate transport device 500 includes a vertical direction driving motor 511, a vertical direction encoder 512, a horizontal direction driving motor 513, a horizontal direction encoder 514, a rotation direction driving motor 515, a rotation direction encoder 516, an upper-hand advancing retreating driving motor 525, an upper-hand encoder 526, a lower-hand advancing retreating driving motor 527, a lower-hand encoder 528, the plurality of reflective photo detectors SA1 to SA5, the transport controller 550 and an operation unit 529. The plurality of reflective photo detectors SA1 to SA5 are provided to correspond to each of the hands H1, H2.

The vertical direction driving motor 511 moves the movement member 510 (FIG. 2) in the vertical direction with the control of the transport controller 550. The vertical direction encoder 512 outputs a signal indicating a rotation angle of the vertical direction driving motor 511 to the transport controller 550. Thus, the transport controller 550 can detect a position of the movement member 510 in the vertical direction.

The horizontal direction driving motor 513 moves the movement member 510 (FIG. 2) in the horizontal direction with the control of the transport controller 550. The horizontal direction encoder 514 outputs a signal indicating a rotation angle of the horizontal direction driving motor 513 to the transport controller 550. Thus, the transport controller 550 can detect a position of the movement member 510 in the horizontal direction.

The rotation direction driving motor 515 rotates the rotation member 520 (FIG. 1) around an axis extending in the vertical direction with the control of the transport controller 550. The rotation direction encoder 516 outputs a signal indicating a rotation angle of the rotation direction driving motor 515 to the transport controller 550. Thus, the transport controller 550 can detect an orientation of the rotation member 520 in a horizontal plane.

The upper-hand advancing retreating driving motor 525 advances and retreats the hand H1 (FIG. 1) on the rotation member 520 in the horizontal direction with the control of the transport controller 550. The upper-hand encoder 526 outputs a signal indicating a rotation angle of the upper-hand advancing retreating driving motor 525 to the transport controller 550. Thus, the transport controller 550 can detect a position of the hand H1 on the rotation member 520.

The lower-hand advancing retreating driving motor 527 advances and retreats the hand H2 (FIG. 2) on the rotation member 520 in the horizontal direction with the control of the transport controller 550. The lower-hand encoder 528 outputs a signal indicating a rotation angle of the lower-hand advancing retreating driving motor 527 to the transport controller 550. Thus, the transport controller 550 can detect a position of the hand H2 on the rotation member 520.

Each of the reflective photo detectors SA1 to SA5 emits linear light upwardly from a light transmission surface ss (FIG. 4) with the control of the transport controller 550. A signal output from each of the reflective photo detectors SA1 to SA5 is supplied to the transport controller 550. Thus, the transport controller 550 calculates the positions of the plurality of portions of the outer peripheral end of the substrate W in the hand H1 based on the output signals of the reflective photo detectors SA1 to SA5 provided at the hand H1 and the pre-stored light amount position information. Similarly, the transport controller 550 calculates the positions of the plurality of portions of the outer peripheral end of the substrate W in the hand H2 based on the output signals of the reflective photo detectors SA1 to SA5 provided at the hand H2 and the pre-stored light amount position information.

The operation unit 529 is connected to the transport controller 550. A user can provide various instructions and information to the transport controller 550 by operating the operation unit 529.

### [3] Determination of Position of Substrate W in Hand H1, H2

In each of the above-mentioned hands H1, H2, an X-Y coordinate system having an X axis and a Y axis is defined. The X axis and the Y axis are located in a horizontal plane parallel to the substrate W held by each of the hands H1, H2 and orthogonally intersect with each other at the reference position of each of the hands H1, H2. As such, the reference position is an origin O. In the present example, the Y axis is defined to be parallel to the advancing retreating direction of each of the hands H1, H2.

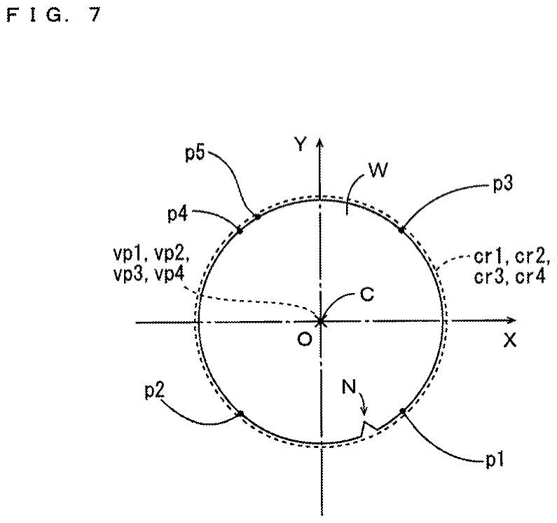

FIG. 7 is a plan view showing one example of the X-Y coordinate system defined in the hand H1. In FIG. 7, the X axis and the Y axis of the XY coordinate system defined in the hand H1 are indicated by the one-dot and dash lines. Further, the reference position is indicated as the origin O. Further, the substrate W held by the hand H1 is indicated by the solid line. In the example of FIG. 7, the center position of the substrate W held by the hand H1 is located at the origin O.

In the substrate transport device 500, the positions of five portions p1 to p5 of the outer peripheral end of the substrate W in the hand H1 are calculated by the reflective photo detectors SA1 to SA5, respectively. The position of the substrate W in the hand H1 is determined based on the calculated positions of the portions p1 to p5. Similarly, the positions of the five portions p1 to p5 of the substrate W in the hand H2 are calculated by the reflective photo detectors SA1 to SA5, and the position of the substrate W in the hand H2 is determined based on the calculated positions of the portions p1 to p5. Based on the determined position of the substrate W, the vertical direction driving motor 511, the horizontal direction driving motor 513, the rotation direction driving motor 515, the upper-hand advancing retreating driving motor 525 and the lower-hand advancing retreating driving motor 527, described above, are controlled. A method of determining the position of the substrate W in the hand H1 will now be described.

First, with the substrate W held by suction on the hand H1, for example, linear light is emitted from the light transmission surfaces ss (FIG. 4) of the reflective photo detectors SA1 to SA5 toward the outer periphery of the substrate W. Part of each emitted light is reflected from the lower surface of the substrate W and incident on the light transmission surfaces ss. Based on the signals that are then output from the reflective photo detectors SA1 to SA5 and the light amount position information respectively corresponding to the reflective photo detectors SA1 to SA5, the positions of the five portions p1 to p5 of the substrate W in the hand H1 are respectively calculated.

Next, four imaginary circles each passing through the positions of three different portions out of the four portions p1, p2, p3, p4 in the X-Y coordinate system are calculated, and the center positions of the four imaginary circles are respectively calculated. Further, a plurality of amounts of deviation among the four center positions are calculated.

In the following explanation, the imaginary circle passing through the portions p1, p2, p3 is referred to as an imaginary circle cr1, the imaginary circle passing through the portions p2, p3, p4 is referred to as an imaginary circle cr2, the imaginary circle passing through the portions p1, p3, p4 is referred to as an imaginary circle cr3 and the imaginary circle passing through the portions p1, p2, p4 is referred to as an imaginary circle cr4. Further, the center positions of the imaginary circles cr1, cr2, cr3, cr4 in the hand H1 are respectively referred to as vp1, vp2, vp3, vp4.

As indicated by the dotted line in FIG. 7, in a case in which all of the plurality of amounts of deviation among the center positions vp1 to vp4 are 0, the four center positions vp1 to vp4 coincide with the center position C of the substrate W in the hand H1. Even in a case in which at least one of the plurality of amounts of deviation is not 0, when all of the plurality of amounts of deviation among the four center positions vp1 to vp4 are equal to or smaller than a predetermined threshold value, the four center positions vp1 to vp4 almost coincide with the center position C of the substrate W in the hand H1. Here, the threshold value is defined to be the acceptable errors between the actual positions and the attachment positions in design (designed positions) of the reflective photo detectors SA1 to SA5 in the hand H1, for example.

In this manner, in a case in which all of the plurality of amounts of deviation are equal to or smaller than the threshold value, a notch N is not present in any of the portions p1 to p4 of the substrate W detected by the reflective photo detectors SA1 to SA4. Therefore, because all of the four imaginary circles cr1 to cr4 represent the position of the substrate W in the hand H1, the position of the substrate W in the hand H1 can be determined based on any or all of the four imaginary circles cr1 to cr4.

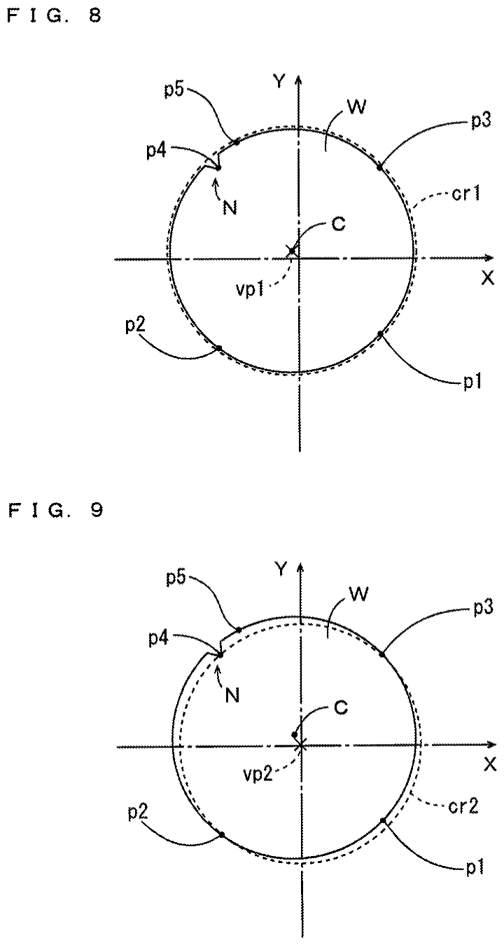

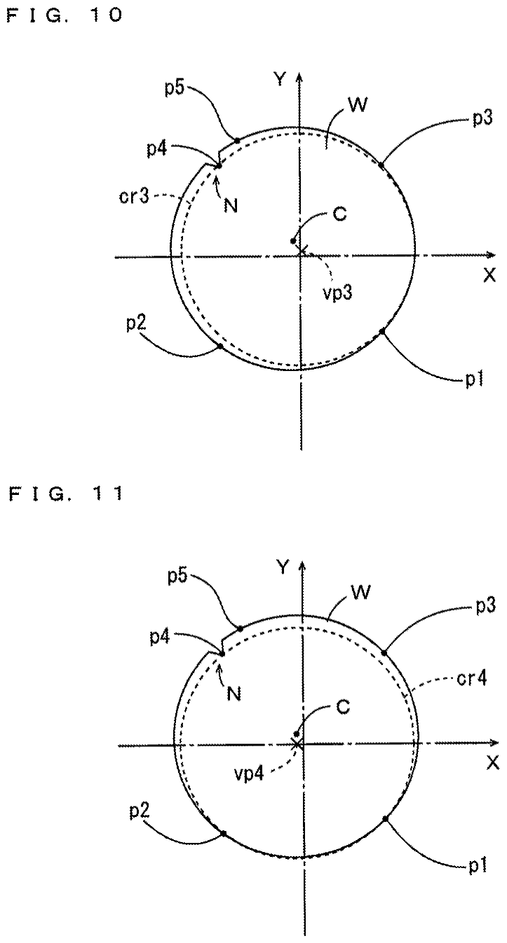

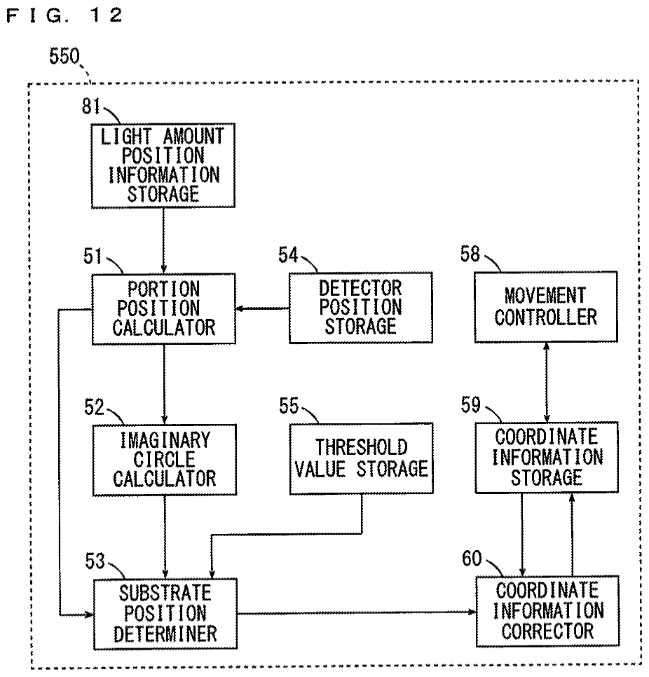

Each of FIGS. 8 to 11 is a plan view showing the positional relationship between the substrate W and each of the four imaginary circles cr1 to cr4 on the hand H1 in a case in which at least one of the plurality of amounts of deviation exceeds the threshold value. The hand H1 is not shown in each of FIGS. 8 to 11. The positional relationship between the substrate W and the imaginary circle cr1 is shown in FIG. 8, and the positional relationship between the substrate W and the imaginary circle cr2 is shown in FIG. 9. Further, the positional relationship between the substrate W and the imaginary circle cr3 is shown in FIG. 10, and the positional relationship between the substrate W and the imaginary circle cr4 is shown in FIG. 11.

In a case in which at least one of the plurality of amounts of deviation exceeds the threshold value, only one center position out of the four center positions vp1 to vp4 (the center position vp1 of the imaginary circle cr1 in the present example) coincides with or almost coincides with the center position C of the substrate W in the hand H1 (FIG. 8). On the other hand, the remaining three center positions (the center positions vp2, vp3, vp4 of the imaginary circles cr2, cr3, cr4 in the present example) deviate from the center position C of the substrate W in the hand H1 to a greater extent than a fixed value (FIGS. 9, 10 and 11).

In this manner, in a case in which at least one of the plurality of amounts of deviation exceeds the threshold value, a notch N is present in any (the portion p4 in the present example) of the portions p1 to p4 of the substrate W detected by the reflective photo detectors SA1 to SA4.

Here, as described above, the distance between the reflective photo detectors SA4, SA5 is smaller than the diameter of the substrate W and larger than the length of the notch N in the circumferential direction of the substrate W. In this case, the portion p5 is spaced apart from the other portions p1 to p4 by distances larger than the length of the notch N in the circumferential direction. Therefore, the notch N is not present in the portion P5 of the substrate W detected by the reflective photo detector SA5. Therefore, the imaginary circle representing the position of the substrate W in each of the hands H1, H2 passes through the position of the portion p5. As such, the imaginary circle passing through the position of the portion p5 out of the four imaginary circles cr1 to cr4 is selected, so that the position of the substrate W in the hand H1 can be determined based on the selected imaginary circle.

### [4] Functional Configuration of Transport Controller 550

FIG. 12 is a block diagram showing the functional configuration of the transport controller 550 according to the first embodiment. The transport controller 550 includes a portion position calculator 51, an imaginary circle calculator 52, a substrate position determiner 53, a detector position storage 54, a threshold value storage 55, a movement controller 58, a coordinate information storage 59, a coordinate information corrector 60 and a light amount position information storage 81. The transport controller 550 is constituted by a CPU (Central Processing Unit), a RAM (Random Access Memory), a ROM (Read Only Memory) and a storage device. The CPU executes a computer program stored in a storage medium such as the ROM or the storage device, so that the function of each of constituent elements of the transport controller 550 is implemented. Part or all of the constituent elements of the transport controller 550 may be implemented by hardware such as an electronic circuit.

Here, it is assumed that the substrate transport device 500 receives the substrate W placed at a predetermined position (hereinafter referred to as a receiving position) in one processing unit, transports the received substrate W and places the substrate W at a predetermined position (hereinafter referred to as a placing position) in another processing unit. The receiving position and the placing position are represented by the coordinates of a fixed coordinate system in regard to the entire substrate transport device 500. The coordinates of the receiving position are referred to as receiving coordinates, and the coordinates of the placing position are referred to as placement coordinates.

The coordinate information storage 59 stores the receiving coordinates of the receiving position and the placement coordinates of the placing position in advance as the coordinate information. Based on the coordinate information (receiving coordinates) stored in the coordinate information storage 59, the movement controller 58 controls the vertical direction driving motor 511, the horizontal direction driving motor 513 and the rotation direction driving motor 515 of FIG. 6 and also controls the upper-hand advancing retreating driving motor 525 or the lower-hand advancing retreating driving motor 527 such that the substrate W is received at the receiving position. At this time, the hand H1 or H2 advances and retreats on the rotation member 520.

The detector position storage 54 stores the designed positions of the plurality of reflective photo detectors SA1 to SA5 on each of the hands H1, H2 as detector information. The light amount position information storage 81 stores the light amount position information corresponding to each of the plurality of reflective photo detectors SA1 to SA5. The portion position calculator 51 calculates the positions of the plurality of portions p1 to p5 of the substrate W in the hand H1 or the hand H2 based on the output signals of the plurality of reflective photo detectors SA1 to SA5, the detector information stored in the detector position storage 54 and the light amount position information stored in the light amount position information storage 81.

The imaginary circle calculator 52 calculates each of the four imaginary circles cr1 to cr4 (FIGS. 7 to 11) based on the positions of the portions p1 to p4 calculated by the portion position calculator 51. The imaginary circle calculator 52 also calculates each of the center positions vp1 to vp4 (FIGS. 7 to 11) of each of the calculated respective imaginary circles cr1 to cr4.

The threshold value storage 55 stores the above-mentioned threshold value. The substrate position determiner 53 calculates a plurality of amounts of deviation among the plurality of center positions vp1 to vp4 calculated by the imaginary circle calculator 52. Further, the substrate position determiner 53 also determines whether all of the plurality of amounts of deviation are equal to or smaller than the threshold value stored in the threshold value storage 55.

In a case in which all of the plurality of amounts of deviation are equal to or smaller than the threshold value, the substrate position determiner 53 determines the position of the substrate W in the hand H1 or the hand H2 based on any or all of the four imaginary circles cr1 to cr4. On the other hand, in a case in which at least one of the plurality of above-mentioned amounts of deviation exceeds the threshold value, the substrate position determiner 53 selects the imaginary circle which passes through the position of the portion p5 calculated by the portion position calculator 51 out of the four imaginary circles cr1 to cr4. Further, the substrate position determiner 53 determines the position of the substrate W in the hand H1 or the hand H2 based on the selected imaginary circle.

The coordinate information corrector 60 calculates the deviation of the center position C of the substrate W with respect to the reference position of the hand H1 or the hand H2 based on the position of the substrate W in the hand H1 or the hand H2 determined by the substrate position determiner 53. Further, the coordinate information corrector 60 corrects the coordinate information (placement coordinates) stored in the coordinate information storage 59 based on the calculated deviation. Based on the coordinate information (placement coordinates) that is stored in the coordinate information storage 59 and corrected, the movement controller 58 controls the vertical direction driving motor 511, the horizontal direction driving motor 513 and the rotation direction driving motor 515 of FIG. 6 and controls the upper-hand advancing retreating driving motor 525 or the lower-hand advancing retreating driving motor 527 such that the substrate that has been received at the receiving position is placed at the placing position. At this time, the hand H1 or the hand H2 advances and retreats on the rotation member 520.

### [5] Work of Substrate Transport Device 500

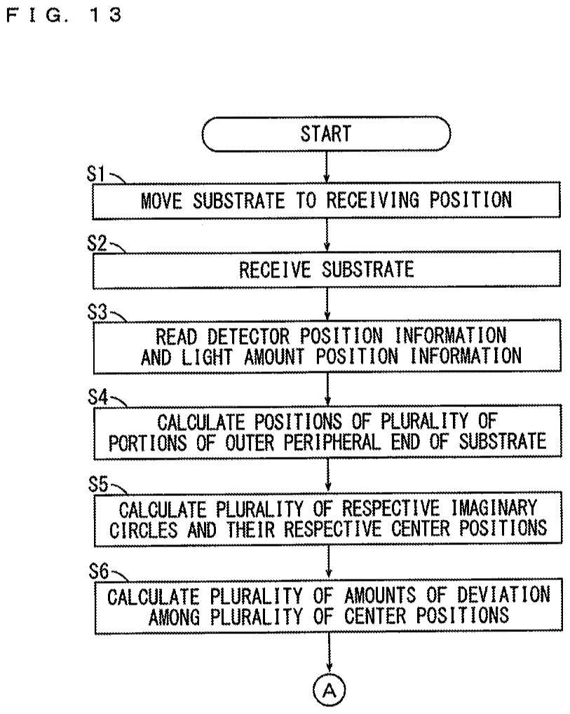

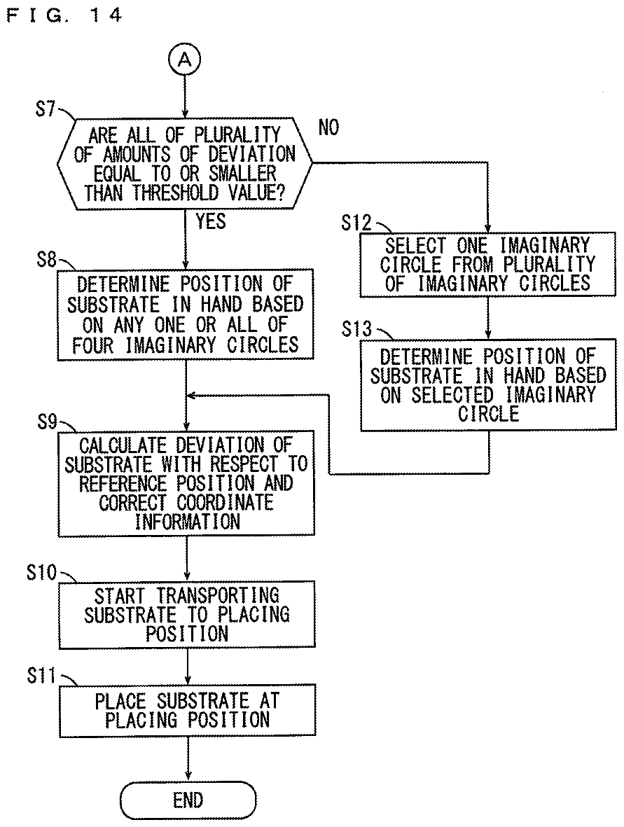

FIGS. 13 and 14 are flowcharts showing the basic work for transporting the substrate W performed by the substrate transport device 500 according to the first embodiment. The work for transporting the substrate W with use of the hand H1 will be described below. In an initial state, the hand H1 is located at the rearmost position on the rotation member 520. Suppose that the substrate W is not held by the hand H1 in the initial state.

Based on coordinate information (receiving coordinates) stored in the coordinate information storage 59, the movement controller 58 of FIG. 12 moves the hand H1 to a position in the vicinity of the receiving position (step S1) and causes the hand H1 to receive the substrate W located at the receiving position by advancing the hand H1 (step S2). Then, the portion position calculator 51 reads detector information and light amount position information from the detector position storage 54 and the light amount position information storage 81 (step S3).

Next, the portion position calculator 51 causes the reflective photo detectors SA1 to SA5 to emit light toward the outer periphery of the substrate W, and calculates the positions of the plurality of portions p1 to p5 of the outer peripheral end of the substrate W in the hand H1 based on the output signals of the reflective photo detectors SA1 to SA5, the detector information and the light amount position information (step S4).

The imaginary circle calculator 52 calculates the four imaginary circles cr1 to cr4 passing through three different portions out of the calculated positions of the portions p1 to p4 of the substrate W and also calculates the center positions vp1 to vp4 of these calculated imaginary circles cr1 to cr4 (step S5).

Then, the substrate position determiner 53 calculates a plurality of amounts of deviation of the plurality of calculated center positions vp1 to vp4 (step S6) and determines whether all of the plurality of calculated amounts of deviation are equal to or smaller than the threshold value stored in the threshold value storage 55 (step S7).

In a case in which all of the plurality of calculated amounts of deviation are equal to or smaller than the threshold value, the substrate position determiner 53 determines the position of the substrate W in the hand H1 based on any or all of the four imaginary circles cr1 to cr4 (step S8).

Then, the coordinate information corrector 60 calculates the deviation of the center position C of the substrate W with respect to the reference position based on the determined position of the substrate W, and corrects the coordinate information (placement coordinates) stored in the coordinate information storage 59 so as to cancel the deviation between the position of the substrate W to be placed by the hand H1 and the placing position based on the result of calculation (step S9).

After that, based on the corrected coordinate information (placement coordinates), the movement controller 58 starts the transport control of the hand H1 such that the substrate W is transported to the placing position (step S10) and the substrate W held by the hand H1 is placed at the placing position (step S11). This makes it possible to accurately place the substrate W at the placing position irrespective of the position of the substrate W in the hand H1.

In the above-mentioned step S7, in a case in which at least one of the plurality of amounts of deviation exceeds the threshold value, the substrate position determiner 53 selects one imaginary circle passing through the position of the portion p5 out of the four imaginary circles cr1 to cr4 (step S12). The substrate position determiner 53 subsequently determines the position of the substrate W in the hand H1 based on the selected imaginary circle (step S13) and proceeds to step S9.

In the above-mentioned transport work, the step S3 may be performed before the step S2 or the step S1. In the above-mentioned transport work, the steps S12 and S13 may be performed instead of the steps S7 and S8. In this case, it is not necessary to set a threshold value in regard to a deviation amount.

In a case in which the center of the substrate W held on each of the hands H1, H2 markedly deviates from the reference position, the outer peripheral end of the substrate W may not be located in the detection regions df1 to df5 of the plurality of reflective photo detectors SA1 to SA5. In this case, even with the light amount position information, the accurate positions of the plurality of portions p1 to p5 of the outer peripheral end of the substrate W cannot be calculated. Therefore, in the above-mentioned step S4, the portion position calculator 51 may stop the transport work in a case in which the output signal of at least one reflective photo detector out of the plurality of reflective photo detectors SA1 to SA5 indicates “the light receiving amount=0” or “the light receiving amount=the maximum light receiving amount a.” Further, in this case, the portion position calculator 51 may output a warning signal representing an abnormality in a holding state of the substrate W by each of the hands H1, H2 to an external device of the substrate transport device 500.

### [6] Effects of First Embodiment

(1) In the above-mentioned substrate transport device 500, linear light is emitted from each of the plurality of reflective photo detectors SA1 to SA5 provided at each of the hands H1, H2 to the outer periphery of the substrate W. In this case, an amount of light reflected from the outer periphery of the substrate W changes in accordance with a position of the outer peripheral end of the substrate W in the direction in which the linear light transmission surfaces ss extend (the advancing retreating direction AB). The output signals of the plurality of reflective photo detectors SA1 to SA4 represent the light receiving amounts of light that is incident on the light transmission surfaces ss. Therefore, with these light receiving amounts, the positions of the plurality of portions p1 to p5 of the outer peripheral end of the substrate W in the direction in which the light transmission surfaces ss of the plurality of reflective photo detectors SA1 to SA5 extend can be calculated. Thus, the work for moving each of the hands H1, H2 to a specific position, etc. in order to calculate the position of the substrate W held by each of the hands H1, H2 is not necessary. Therefore, at a point in time at which the substrate W is arranged on each of the hands H1, H2, the position of the substrate W with respect to each of the hands H1, H2 can be determined. As a result, a period of time required for determination of the positions of the substrates W can be reduced. Further, based on the result of determination in regard to the positions of the substrates W, the substrates W held by the hands H1, H2 can be transported to placing positions with high accuracy.

(2) The plurality of reflective photo detectors SA1 to SA5 extend in parallel with the advancing retreating direction AB. Further, out of the plurality of reflective photo detectors SA1 to SA5, the reflective photo detectors SA1, SA2 are arranged not to overlap with the reflective photo detectors SA3, SA4 in the advancing retreating direction AB. In particular, the above-mentioned reflective photo detectors SA1 to SA4 are arranged to be respectively located in the four regions into which one region is divided by the X axis and the Y axis defined on the each of hands H1, H2. With this arrangement, as compared to a case in which the reflective photo detectors SA1 to SA4 are arranged in a concentrated manner in one or three regions out of the four regions into which the one region is divided by the X axis and the Y axis, for example, the plurality of portions p1 to p4 of the substrate W to be detected are distributed more uniformly on the outer peripheral end of the substrate W. Thus, the positions of the plurality of portions p1 to p4 of the outer peripheral end of the substrate W can be calculated with high accuracy based on the light amount position information.

### 2. Second Embodiment

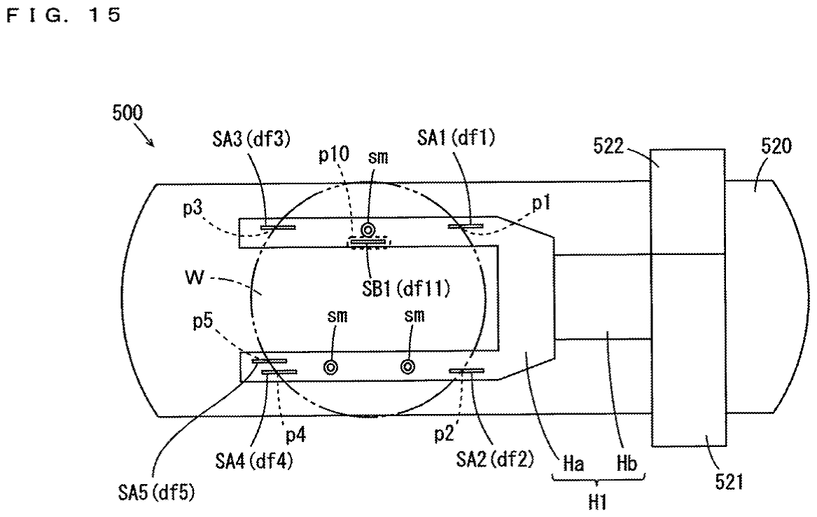

Differences of a substrate transport device 500 according to a second embodiment from the substrate transport device 500 according to the first embodiment will be described. FIG. 15 is a plan view of the substrate transport device 500 according to the second embodiment.

As shown in FIG. 15, the substrate transport device 500 according to the second embodiment is further provided with a reflective photo detector SB1 on each of the hands H1, H2 in addition to the configuration of the substrate transport device 500 according to the first embodiment. The reflective photo detector SB1 is a fiber sensor basically having the same configuration as that of the reflective photo detectors SA1 to SA5 and arranged in the vicinity of one suction portion sm of the plurality of suction portions sm.

In the substrate transport device 500, the type of the substrate W held by each of the hands H1, H2 is not limited to one. The reflectance of the substrate W with respect to the light emitted from the reflective photo detectors SA1 to SA5 differs depending on the type of the substrate. As described in the first embodiment, the value of the maximum light receiving amount a of the light amount position information corresponding to each of the reflective photo detectors SA1 to SA5 is defined based on the reflectance of the substrate W. Therefore, in a case in which the designed position of each of the reflective photo detectors SA1 to SA5 and the reflectance of the substrate W can be discovered, the light amount position information corresponding to each of the reflective photo detectors SA1 to SA5 can be generated for the substrate W held by each of the hands H1, H2. That is, it is not necessary for the light amount position information storage 81 of FIG. 12 to store a large amount of light amount position information in advance.

As such, in the substrate transport device 500 according to the present embodiment, the reflective photo detector SB1 is used to obtain the reflectance of the substrate W. For example, the reflective photo detector SB1 provided at the hand H1 emits linear light toward a portion inward of the outer periphery of the substrate W held by the hand H1 along a detection region df11. In the following description, a portion of the substrate W that receives the light emitted from the reflective photo detector SB1 is referred to as an inner portion p10.

In this case, all of the light emitted from a light transmission surface ss of the reflective photo detector SB1 and reflected from the substrate W is reflected from the inner portion p10 and incident on the light transmission surface ss. At this time, the reflectance of the substrate W is calculated based on an amount of light emitted from the light transmission surface ss and an output signal of the reflective photo detector SB1. Further, the light amount position information corresponding to each of the reflective photo detectors SA1 to SA5 of the hand H1 is generated based on the calculated reflectance of the substrate W and the detector information (the designed positions of the reflective photo detectors SA1 to SA5).

The reflective photo detector SB1 (not shown) provided at the hand H2 also emits linear light toward a portion inward of the outer periphery of the substrate W held by the hand H2 similarly to the reflective photo detector SB1 provided at the hand H1. Thus, with the method similar to that of the above-mentioned example, the light amount position information corresponding to each of the reflective photo detectors SA1 to SA5 of the hand H2 is generated.

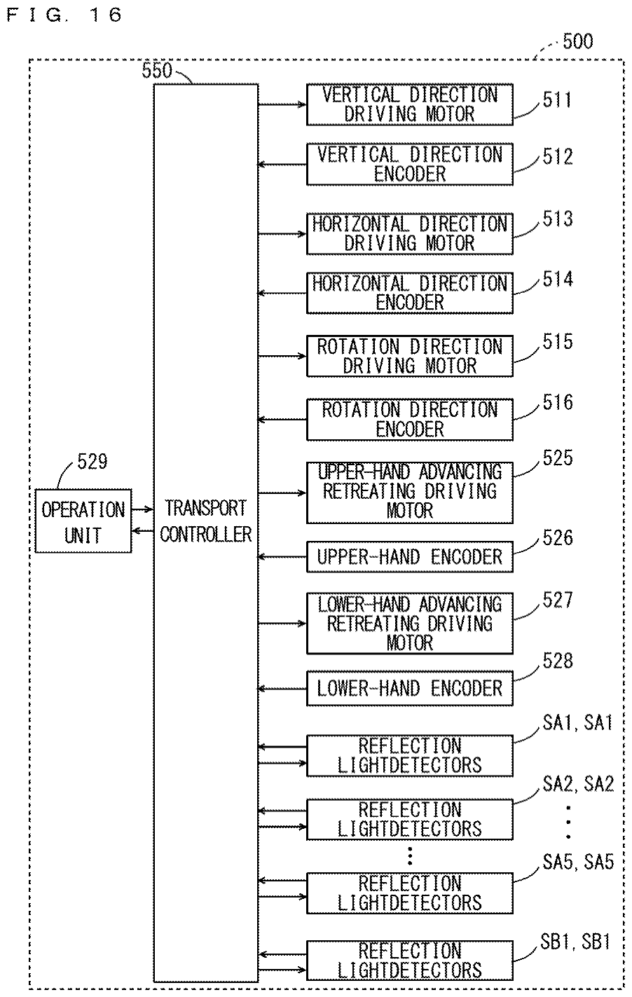

FIG. 16 is a block diagram showing the configuration of a control system of the substrate transport device 500 according to the second embodiment. As shown in FIG. 16, the substrate transport device 500 according to the second embodiment includes the reflective photo detector SB1 provided at each of the hands H1, H2 in addition to the configuration of the substrate transport device 500 of FIG. 6 according to the first embodiment. The reflective photo detector SB1 emits linear light upwardly from the light transmission surface ss with the control of the transport controller 550. A signal output from the reflective photo detector SB1 is supplied to the transport controller 550.

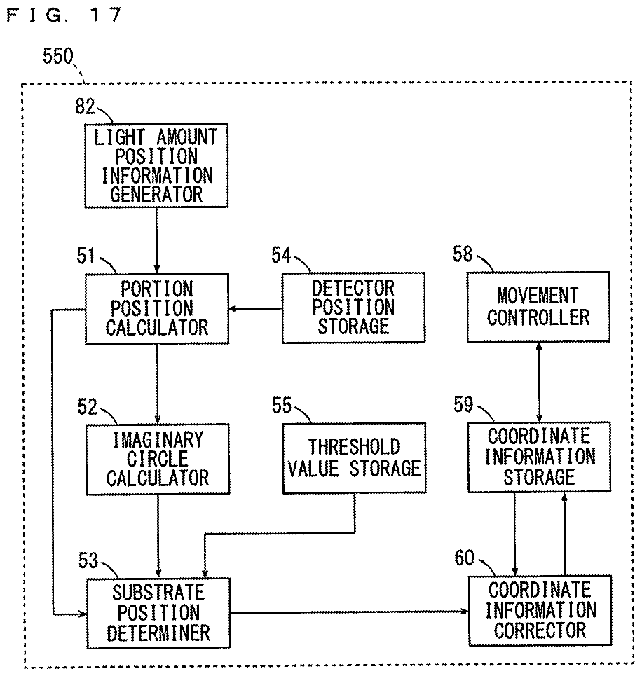

FIG. 17 is a block diagram showing the functional configuration of the transport controller 550 according to the second embodiment. The transport controller 550 according to the present embodiment includes a light amount position information generator 82 instead of the light amount position information storage 81 of the configuration of the transport controller 550 of FIG. 12 according to the first embodiment.

The light amount position information generator 82 generates the light amount position information corresponding to each of the reflective photo detectors SA1 to SA5 of the hand H1 based on an amount of light output from the reflective photo detector SB1 of the hand H1, an output signal of the reflective photo detector SB1 and the detector information stored in the detector position storage 54 Further, the light amount position information generator 82 generates the light amount position information corresponding to each of the reflective photo detectors SA1 to SA5 of the hand H2 based on an amount of light output from the reflective photo detector SB1 of the hand H2, an output signal of the reflective photo detector SB1 and the detector information stored in the detector position storage 54.

Thus, the portion position calculator 51 calculates the positions of the plurality of portions p1 to p5 of the substrate W in the hand H1 or the hand H2 based on the output signals of the plurality of reflective photo detectors SA1 to SA5, the detector information stored in the detector position storage 54 and the light amount position information generated by the light amount position information generator 82.

FIG. 18 is a flowchart showing part of the basic work for transporting the substrate W performed by the substrate transport device 500 according to the second embodiment. In the work for transporting the substrate W according to the present embodiment, the work similar to the steps S1 and S2 of FIG. 12 according to the first embodiment is performed, and then the light amount position information generator 82 generates the light amount position information using the reflective photo detector SB1 (step S31). Thereafter, the steps S4 to S13 of FIGS. 12 and 13 are performed similarly to the first embodiment.

In the substrate transport device 500 according to the present embodiment, even in a case in which the reflectance of light with respect to the substrate W is not known and the light amount position information is not present, the light amount position information corresponding to each of the reflective photo detectors SA1 to SA5 is generated based on the output signal of the reflective photo detector SB1. Thus, based on the generated light amount position information, the positions of the plurality of portions p1 to p5 of the outer peripheral end of the substrate W can be calculated with high accuracy.

The reflective photo detector SB1 is located close to one suction portion sm as compared to the reflective photo detectors SA1 to SA5. With each suction portion sm holding the lower surface of the substrate W by suction, the height of the inner portion p10 of the substrate W located in the vicinity of the suction portion sm is kept substantially constant by the suction portion sm. Therefore, variations in condition for calculating the reflectance of the substrate W, that is, condition for generating the light amount position information is reduced, and the light amount position information can be generated appropriately. As a result, the positions of the plurality of portions of the outer peripheral end of the substrate can be calculated with higher accuracy based on the appropriately generated light amount position information.

### 3. Third Embodiment

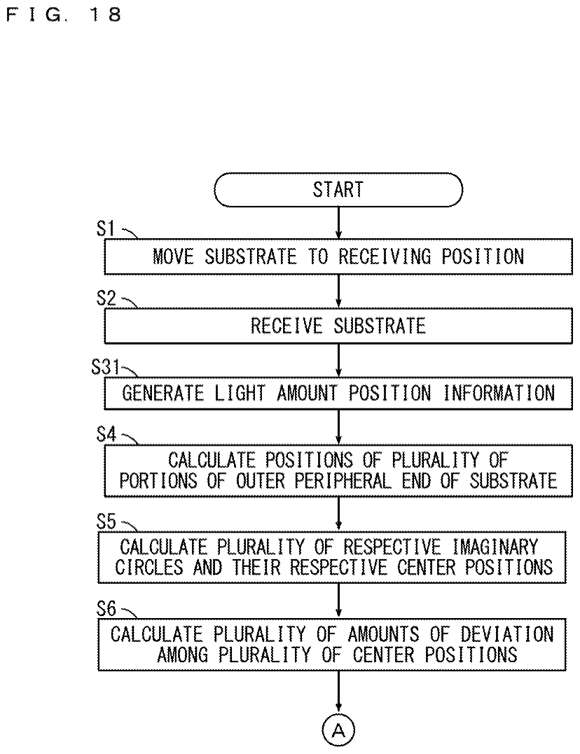

Differences of a substrate transport device 500 according to a third embodiment from the substrate transport device 500 according to the second embodiment will be described. FIG. 19 is a plan view of the substrate transport device 500 according to the third embodiment.

As shown in FIG. 19, the substrate transport device 500 according to the third embodiment is further provided with reflective photo detectors SC1 to SC4 on each of the hands H1, H2 in addition to the configuration of the substrate transport device 500 according to the second embodiment. The reflective photo detectors SC1 to SC4 are fiber sensors having the same configuration as that of the reflective photo detectors SA1 to sA5.

The reflective photo detector SC1 is arranged in the vicinity of the reflective photo detector SA1 in a plan view and is arranged such that an entire detection region df21 of the reflective photo detector SC1 overlaps with the substrate W held by each of the hands H1, H2. The reflective photo detector SC2 is arranged in the vicinity of the reflective photo detector SA2 in a plan view and is arranged such that an entire detection region df22 of the reflective photo detector SC2 overlaps with the substrate W held by each of the hands H1, H2. The reflective photo detector SC3 is arranged in the vicinity of the reflective photo detector SA3 in a plan view and is arranged such that an entire detection region df23 of the reflective photo detector SC3 overlaps with the substrate W held by each of the hands H1, H2. Further, the reflective photo detector SC4 is arranged in the vicinity of the reflective photo detectors SA4, SA5 in a plan view and is arranged such that an entire detection region df24 of the reflective photo detector SC4 overlaps with the substrate W held by each of the hands H1, H2.

As described above, each of the reflective photo detectors SA1 to SA5 is a fiber sensor. Light guided from the main body of the fiber sensor to the fiber unit is emitted from the light transmission surface ss while having a predetermined divergence angle. Therefore, in a case in which the distances between the reflective photo detectors SA1 to SA5 and the substrate W (the height in the present example) change, an amount of light received by the reflective photo detectors SA1 to SA5 changes in accordance with the change of these distances.

For example, when the distance between the reflective photo detector SA1 and the substrate W increases with the position of the substrate W on the XY coordinates fixed, a decrease amount of an amount of light that returns to the light transmission surface ss increases. On the other hand, when the distance between the reflective photo detector SA1 and the substrate W decreases with the position of the substrate W on the XY coordinates fixed, a decrease amount of an amount of light that returns to the light transmission surface ss decreases. Therefore, in a case in which the distance between the reflective photo detector SA1 and the portion p1 of the substrate W is different from the distance between the reflective photo detector SB1 and the inner portion p10 of the substrate W during generation of the light amount position information, accuracy of calculation of the position of the portion p1 is degraded. Therefore, the larger the divergence angle of emitted light is, the larger the degree of change in light receiving amount of the reflective photo detectors SA1 to SA5 caused by a change of the distances between the reflective photo detectors SA1 to SA5 and the substrate W is.

As such, in order to suppress degradation of accuracy of calculation of the positions of the portions p1 to p5 caused by variations in distance between each of the reflective photo detectors SA1 to SA5, and SB1, and the substrate W, the difference between the height of the inner portion p10 of the substrate W and the height of each of the portions p1 to p5 of the substrate W is acquired.

Specifically, an output signal of the reflective photo detector SB1 is acquired as the height of the inner portion p10 of the substrate W during generation of the light amount position information. A light receiving amount indicated by this output signal is referred to as a reference light receiving amount. Further, an output signal of each of the reflective photo detectors SC1, SC2, SC3 is acquired as the height of each of the portions p1, p2, p3 of the substrate W during generation of the light amount position information. Light receiving amounts indicated by the output signals of the reflective photo detectors SC1, SC2, SC3 are referred to as first, second and third light receiving amounts. Further, an output signal of the reflective photo detector SC4 is acquired as the height of each of the inner portions p4, p5 of the substrate W during generation of the light amount position information. A light receiving amount indicated by the output signal of the reflective photo detector SC4 is referred to as a fourth light receiving amount.

In this case, the difference between the height of the inner portion p10 of the substrate W and the height of the portion p1 of the substrate W can be represented by the ratio of the first light receiving amount with respect to the reference light receiving amount, for example. Further, the difference between the height of the inner portion p10 of the substrate W and the height of the portion p2 of the substrate W can be represented by the ratio of the second light receiving amount with respect to the reference light receiving amount, for example. Further, the difference between the height of the inner portion p10 of the substrate W and the height of the portion p3 of the substrate W can be represented by the ratio of the third light receiving amount with respect to the reference light receiving amount, for example. Further, the difference between the height of the inner portion p10 of the substrate W and the height of each of the portions p4, p5 of the substrate W can be represented by the ratio of the fourth light receiving amount with respect to the reference light receiving amount, for example.

With each of the above-mentioned ratios, the positions of the portions p1 to p5 of the substrate W calculated based on the output signals of the reflective photo detectors SA1 to SA5 can be corrected such that errors in calculation of positions caused by variations in height of the inner portion p10 and the portions p1 to p5 of the substrate W are canceled.

For example, it is assumed that the portion p1 of the substrate W is calculated to be located at a position farther rearward than the front end of the reflective photo detector SA1 in the advancing retreating direction AB by 1 mm based on the output signal of the reflective photo detector SA1 and the light amount position information. In this case, in a case in which the ratio of the first light receiving amount with respect to the reference light receiving amount is 70%, it can be determined by correcting the above-mentioned result of determination that the portion p1 of the substrate W is located at a position farther rearward than the front end of the reflective photo detector SA1 by 1.429 mm.

Further, it is assumed that the portion p2 of the substrate W is calculated to be located at a position farther rearward than the front end of the reflective photo detector SA2 in the advancing retreating direction AB by 1.1 mm based on the output signal of the reflective photo detector SA2 and the light amount position information. In this case, in a case in which the ratio of the second light receiving amount with respect to the reference light receiving amount is 80%, it can be determined by correcting the above-mentioned result of determination that the portion p2 of the substrate W is located at a position farther rearward than the front end of the reflective photo detector SA2 by 1.375 mm.

Further, it is assumed that the portion p3 of the substrate W is calculated to be located at a position farther forward than of the rear end of the reflective photo detector SA3 in the advancing retreating direction AB by 1.2 mm based on the output signal of the reflective photo detector SA3 and the light amount position information. In this case, in a case in which the ratio of the third light receiving amount with respect to the reference light receiving amount is 90%, it can be determined by correcting the above-mentioned result of determination that the portion p3 of the substrate W is located at a position farther forward than the rear end of the reflective photo detector SA3 by 1.333 mm.

Further, it is assumed that the portion p4 of the substrate W is calculated to be located at a position farther forward than the rear end of the reflective photo detector SA4 in the advancing retreating direction AB by 1.3 mm based on the output signal of the reflective photo detector SA4 and the light amount position information. In this case, in a case in which the ratio of the fourth light receiving amount with respect to the reference light receiving amount is 100%, it can be determined by correcting the above-mentioned result of determination that the portion p4 of the substrate W is located at a position farther forward than the rear end of the reflective photo detector SA4 by 1.3 mm.

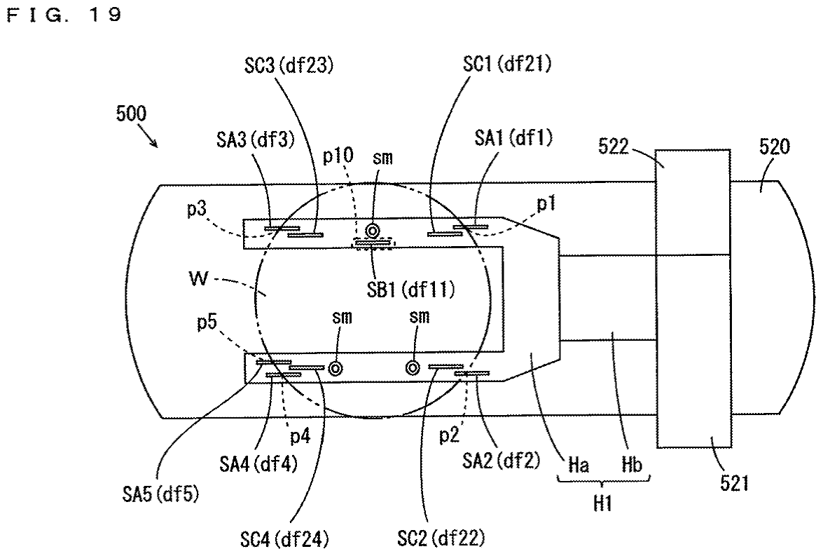

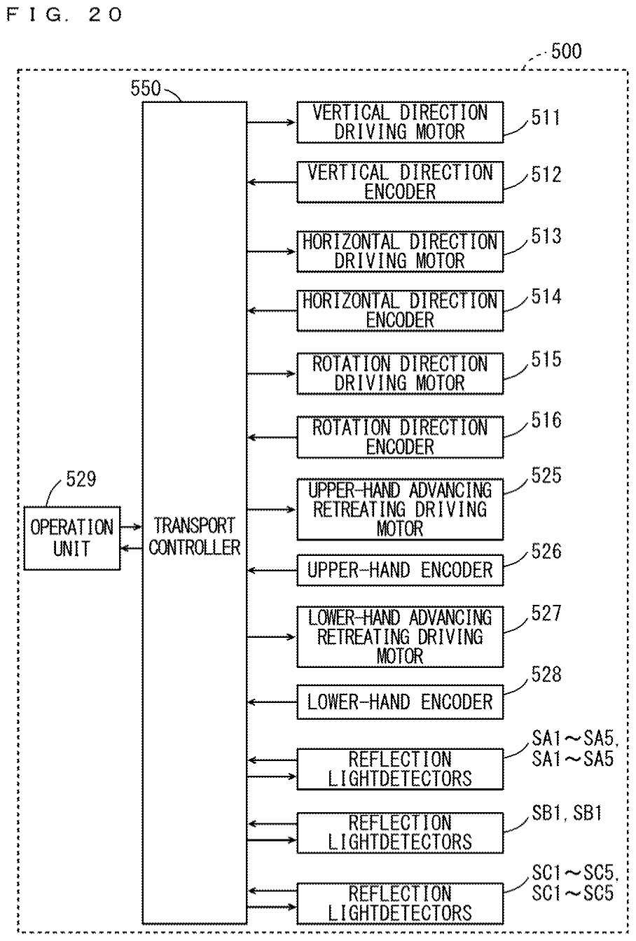

FIG. 20 is a block diagram showing the configuration of the control system of the substrate transport device 500 according to the third embodiment. As shown in FIG. 20, the substrate transport device 500 according to the third embodiment includes the reflective photo detectors SC1 to SC5 provided in each of the hands H1, H2 in addition to the configuration of the substrate transport device 500 of FIG. 16 according to the second embodiment. The reflective photo detectors SC1 to SC5 emit linear light upwardly from the light transmission surfaces ss with the control of the transport controller 550. Signals output from the reflective photo detectors SC1 to SC5 are supplied to the transport controller 550.

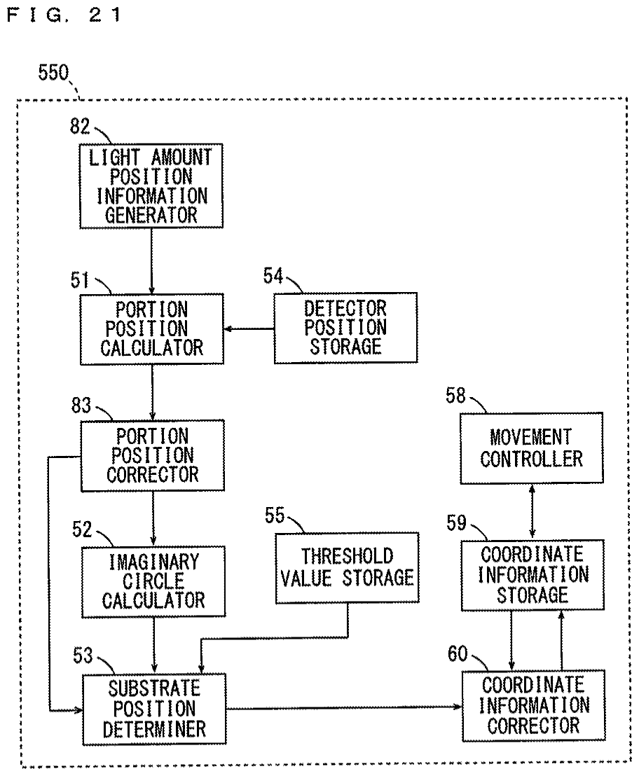

FIG. 21 is a block diagram showing the functional configuration of the transport controller 550 according to the third embodiment. The transport controller 550 according to the present embodiment includes a portion position corrector 83 in addition to the configuration of the transport controller 550 of FIG. 17 according to the second embodiment.

The portion position corrector 83 corrects the positions of the plurality of portions p1 to p5 of the substrate W calculated by the portion position calculator 51 based on the output signals of the reflective photo detectors SB1, SC1 to SC5 of the hand H1. In this case, the imaginary circle calculator 52 calculates the four imaginary circles cr1 to cr4 (FIGS. 7 to 11) based on the positions of the portions p1 to p4 corrected by the portion position corrector 83.

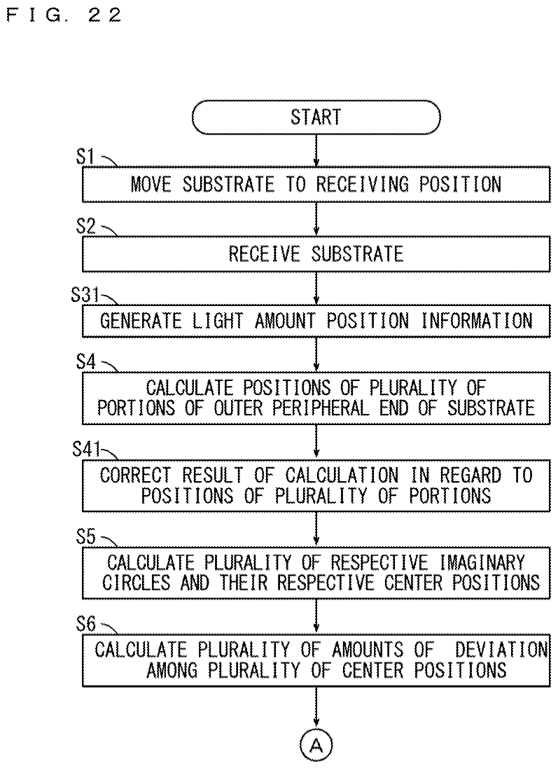

FIG. 22 is a flowchart showing part of the basic work for transporting the substrate W performed by the substrate transport device 500 according to the third embodiment. In the work for transporting the substrate W according to the present embodiment, the similar work to the steps S1, S2, S31 and S4 of FIG. 18 according to the second embodiment is performed, and then the portion position corrector 83 corrects the positions of the plurality of portions p1 to p5 of the outer peripheral end of the substrate W calculated in the step S4 using the reflective photo detectors SC1 to SC4 (step S41). Thereafter, the steps S5 to S13 of FIGS. 12 and 13 are performed similarly to the first embodiment.

In the substrate transport device 500 according to the present embodiment, the light position information is generated when the inner portion p10 of the substrate W is irradiated with light. The heights of the plurality of portions p1 to p5 of the outer peripheral end of the substrate W with respect to the height of the inner portion p10 are acquired by the reflective photo detectors SC1 to SC4. The positions of the plurality of portions p1 to p5 of the substrate W calculated based on the output signals of the reflective photo detectors SA1 to SA5 are corrected based on the heights of the plurality of portions p1 to p5. Thus, the positions of the plurality of portions p1 to p5 of the outer peripheral end of the substrate W can be calculated with higher accuracy.

In the present embodiment, the common reflective photo detector SC4 is used for the two portions p4, p5 in order to acquire the heights of the portions p4, p5 of the substrate W. The present invention is not limited to this example. Two reflective photo detectors for respectively acquiring the heights of the portions p4, p5 of the substrate W may be provided in the vicinity of the reflective photo detectors SA4, SA5.

### 4. Fourth Embodiment

Differences of a substrate transport device 500 according to the fourth embodiment from the substrate transport device 500 according to the first embodiment will be described. The substrate transport device 500 according to the present embodiment can determine the position of the substrate W with respect to the hand H1 with the substrate W held on the hand H1 and the hand H1 arranged below the substrate W supported by the supporter. Further, the position of the substrate W with respect to the hand H2 can be determined with the substrate W held on the hand H2 and the hand H2 arranged below the substrate W supported by the supporter.

In the following description, a control mode of the transport controller 550 in which the position of the substrate W with respect to each of the hands H1, H2 is determined with the substrate W held on each of the hands H1, H2 is referred to as a first control mode. On the other hand, a control mode of the transport controller 550 in which the position of the substrate W with respect to each of the hands H1, H2 is determined with each of the hands H1, H2 arranged below the substrate W supported by the supporter is referred to as a second control mode. A user designates a control mode of the transport controller 550 by operating the operation unit 529 of FIG. 6, for example. Thus, the transport controller 550 controls each component of the substrate transport device 500 in the designated control mode in response to designation made by the user.

The work of the substrate transport device 500 when the transport controller 550 is in the first control mode is as described in the first embodiment. Thus, coordinate information is corrected in accordance with a position of the substrate W held by each of the hands H1, H2 in each of the hands. On the other hand, the second control mode can be effectively utilized in a case in which the positional relationship between each of the hands H1, H2 and the substrate W is adjusted right before the substrate W is held by each of the hands H1, H2, for example, or in a case in which teaching of the substrate transport device 500 is performed. One example of the specific work of the substrate transport device 500 when the transport controller 550 is in the second control mode will be described below.

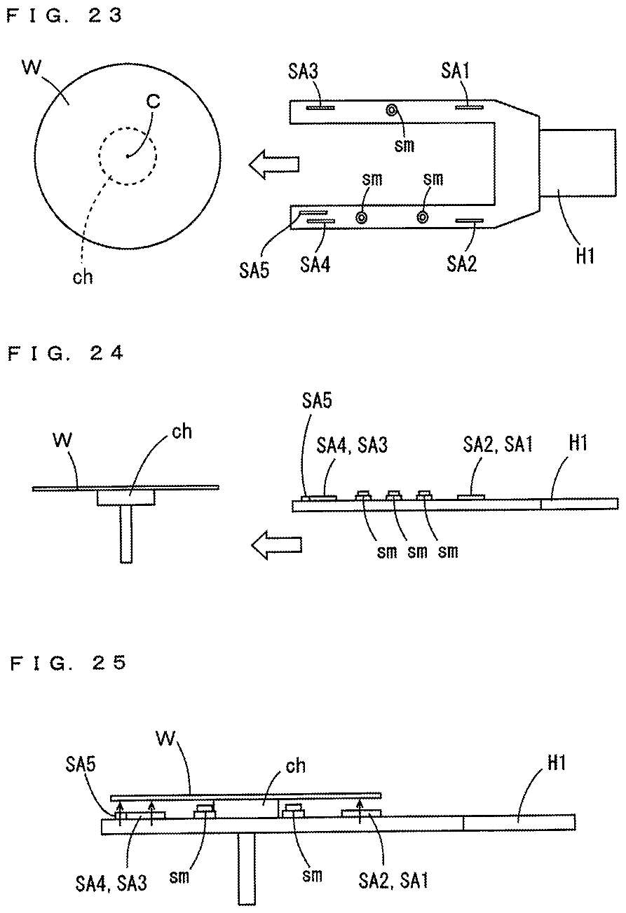

FIGS. 23 to 27 are diagrams for explaining one example of the work of the substrate transport device 500 when the transport controller 550 according to the fourth embodiment is in the second control mode. For example, a spin chuck ch is provided in one processing unit as a supporter. Further, as shown in the plan view of FIG. 23 and the side view of FIG. 24, the substrate W is held on the spin chuck ch. Further, the center position C of the substrate W held on the spin chuck ch is set as a receiving position, and the hand H1 is to receive the substrate W on the spin chuck ch.

In this case, as indicated by the outlined arrows in FIGS. 23 and 24, the hand H1 moves toward a position slightly farther downward than the upper surface of the spin chuck ch and the receiving position. Thus, as shown in the side view of FIG. 25, the hand H1 is held at a position below the substrate W held by the spin chuck ch. Here, the distance between each of the suction portions sm of the hand H1 and the substrate W in the vertical direction is maintained about several millimeters to several tens of millimeters, for example.

In this state, as indicated by the solid arrows in FIG. 25, linear light is emitted from the light transmission surfaces ss of the reflective photo detectors SA1 to SA5. At this time, in a case in which the distance between each of the reflective photo detectors SA1 to SA5 and the substrate W is in a predetermined range, the light reflected from the outer periphery of the lower surface of the substrate W returns to each of the reflective photo detectors SA1 to SA5. Thus, even in a case in which the substrate W is not held by the hand H1, the positions (the positions on the XY coordinates) of the plurality of portions p1 to p5 of the outer peripheral end of the substrate W in the hand H1 can be calculated based on the output signals of the reflective photo detectors SA1 to SA5. The position of the substrate W with respect to the hand H1 can be determined based on a result of calculation.

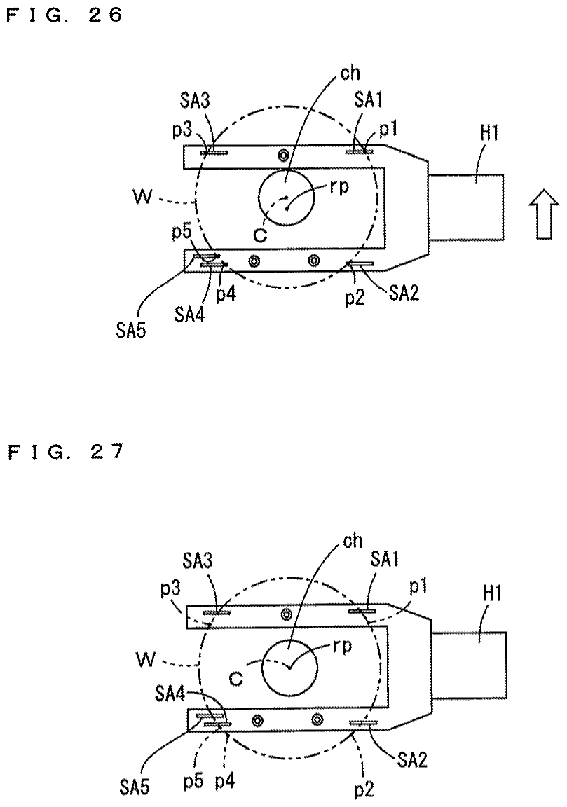

It is assumed that the center position C of the substrate W deviates from a reference position rp of the hand H1 as shown in the plan view of FIG. 26 as the result of determination of the position of the substrate W with respect to the hand H1. In this case, as indicated by the outlined arrow in FIG. 26, the hand H1 is moved to cancel the deviation based on the result of determination. As a result, as shown in the plan view of FIG. 27, the center position C of the substrate W coincides with the reference position rp of the hand H1. In each of FIGS. 26 and 27, the substrate W held by suction by the spin chuck ch is indicated by the two-dots and dash line.

As described above, the position of the hand H1 with respect to the substrate W is adjusted such that the center position C of the substrate W coincides with the reference position rp before the substrate W held by the spin chuck ch is received by the hand H1. In a case in which the hand H1 receives the substrate W in this state, it is not necessary to correct the coordinate information (placement coordinates) of transport destination.

During teaching in regard to reception of the substrate W held by the spin chuck ch, the substrate W is first held by suction on the spin chuck ch such that the center of the substrate W coincides with the rotational center of the spin chuck ch. Thereafter, a series of work show in FIGS. 23 to 27 is performed. In this case, the final position of the hand H1 in the horizontal direction can be determined as receiving coordinates or placement coordinates.

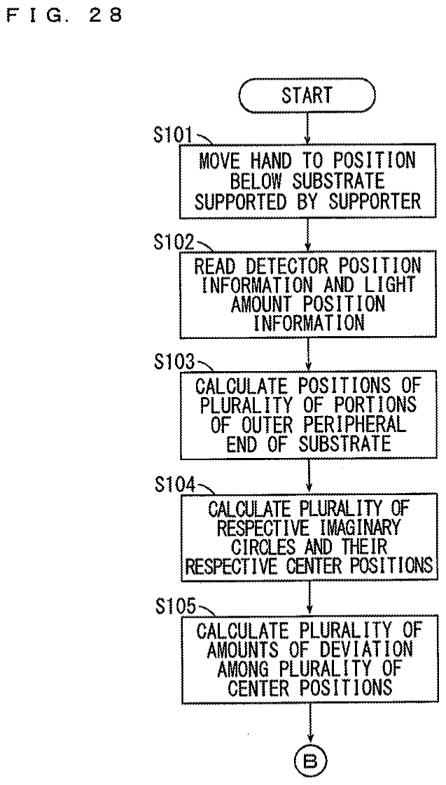

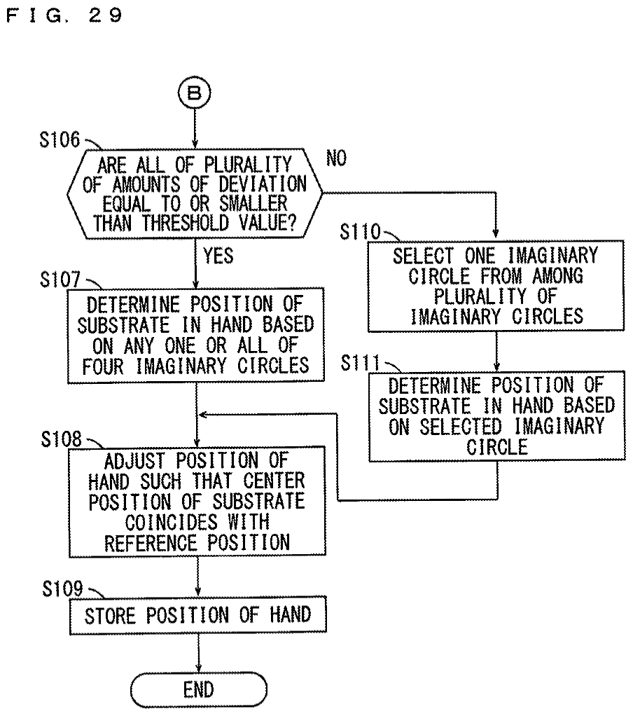

FIGS. 28 and 29 are flowcharts showing the work for adjusting the position of the hand H1 in the second work mode of the substrate transport device 500 according to the fourth embodiment. In an initial state, the substrate W is supported at a predetermined position on a supporter (the spin chuck ch of FIG. 23, for example) provided in one processing unit, for example. Further, in the coordinate information storage 59 of FIG. 12, the coordinate information temporarily representing the position of one processing unit on the supporter is stored. Further, it is assumed that the hand H1 in the initial state does not hold the substrate W.

The movement controller 58 of FIG. 12 moves the hand H1 to a position below the substrate W supported by the supporter based on the coordinate information stored in the coordinate information storage 59 (step S101). Then, the portion position calculator 51 of FIG. 12 reads the detector information and the light amount position information from the detector position storage 54 and the light amount position information storage 81 of FIG. 12 (step S102).

Thereafter, similarly to the steps S4, S5 and S6 of FIG. 13, the positions of the plurality of portions p1 to p5 of the outer peripheral end of the substrate W are calculated, the plurality of imaginary circles cr1 to cr4 and their center positions vp1 to vp4 are calculated, and a plurality of amounts of deviation among the plurality of the center positions vp1 to vp4 are calculated (steps S103, S104 and S105).

Further, similarly to the step S7 of FIG. 14, whether all of the plurality of amounts of deviation calculated in the step S105 are equal to or smaller than a threshold value stored in the threshold value storage 55 of FIG. 12 is determined (step S106). Then, in a case in which all of the plurality of amounts of deviation are equal to or smaller than the threshold value, the same process as the step S8 of FIG. 14 is performed (step S107). On the other hand, in a case in which at least one of the plurality of amounts of deviation exceeds the threshold value, the same process as the steps S12 and S13 of FIG. 14 is performed (steps S110 and S111).

After the step S107 or the step S111, the movement controller 58 adjusts the position of the hand H1 such that the center position C of the substrate W coincides with the reference position rp (step S108). Then, the coordinate information storage 59 of FIG. 12 stores the coordinates at which the hand 1 is located at a current point in time (step S109). Thus, the work for adjusting the position of the hand H1 ends. The work for adjusting the position of the hand H2 is performed similarly to the work for adjusting the position of the hand H1. After the work for adjusting the position of each of the hands H1, H2 is performed, each of the hands H1, H2 may receive the substrate W and transport the received substrate W to another processing unit.

In the substrate transport device 500 according to the present embodiment, even in a case in which the substrate W is being held by each of the hand H1, H2 or each of the hands H1, H2 is arranged below the substrate W supported by the supporter, the position of the substrate Win each of the hands H1, H2 can be determined. Thus, based on a result of determination, the substrate can be transported with high accuracy and the teaching of the substrate transport device 500 can be performed with high accuracy.

While the substrate transport device 500 according to the present embodiment has the same configuration as that of the substrate transport device 500 according to the first embodiment except that the transport controller 550 is workable in the first and second control modes, the present invention is not limited to this. The substrate transport device 500 according to the present embodiment may have the same configuration as that of the substrate transport device 500 according to each of the second and third embodiments except that the transport controller 550 is workable in the first and second control modes. That is, in the substrate transport device 500 according to each of the second and third embodiments, the transport controller 550 may be configured to be workable in the above-mentioned first and second control modes.

### 5. Fifth Embodiment

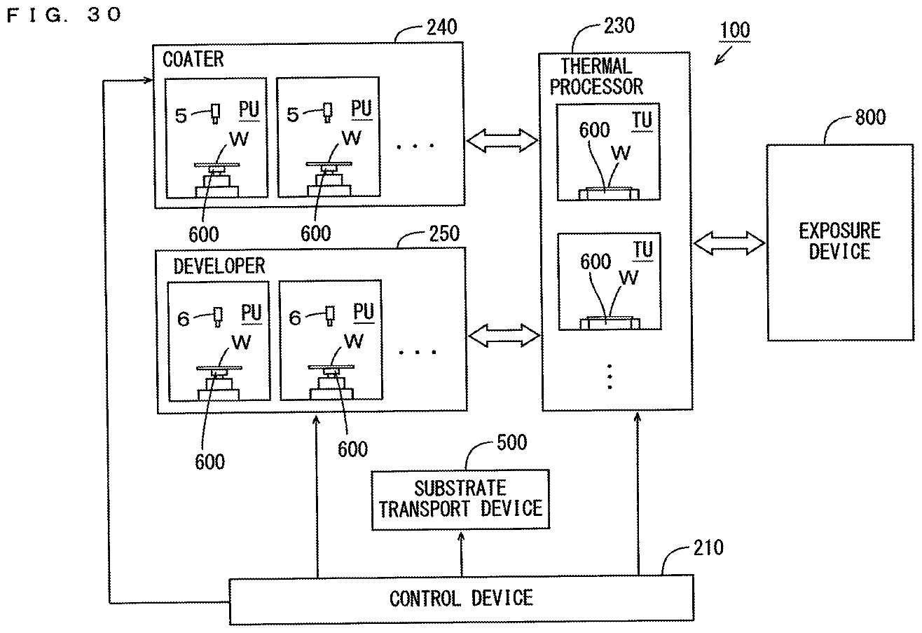

FIG. 30 is a schematic block diagram showing the entire configuration of a substrate processing apparatus including the substrate transport device 500 according to any one of the first to fourth embodiments. As shown in FIG. 30, the substrate processing apparatus 100 is provided to be adjacent to an exposure device 800 and includes a control device 210, the substrate transport device 500 according to any one of the first to fourth embodiments, a thermal processor 230, a coater 240 and a developer 250.

The control device 210 includes a CPU, a memory or a microcomputer, for example, and controls the work of the substrate transport device 500, the thermal processor 230, the coater 240 and the developer 250. Further, the control device 210 provides an instruction for positioning each of the hands H1, H2 of the substrate transport device 500 at the position of the supporter of a predetermined processing unit to the transport controller 550.

The substrate transport device 500 transports the substrate W among the thermal processor 230, the coater 240, the developer 250 and the exposure device 800. Each of the coater 240 and the developer 250 includes a plurality of processing units PU. In a processing unit PU provided in the coater 240, a spin chuck is provided as a supporter 600. In the processing unit PU, a processing liquid nozzle 5 for supplying a processing liquid for forming a resist film on the substrate W rotated by the spin chuck is provided. Thus, a resist film is formed on the unprocessed substrate W. Exposure processing is performed on the substrate W on which the resist film is formed in the exposure device 800.

In a processing unit PU provided in the developer 250, a development liquid nozzle 6 for supplying a development liquid to the substrate W rotated by the spin chuck is provided. Thus, the substrate W on which the exposure processing has been performed by the exposure device 800 is developed.

The thermal processor 230 includes a plurality of processing units TU that perform heating processing or cooling processing on the substrate W. In a processing unit TU, a temperature adjusting plate is provided as a supporter 600. The temperature adjusting plate is a heating plate or a cooling plate. In the thermal processor 230, the thermal processing is performed on the substrate W before and after the coating processing by the coater 240, the development processing by the developer 250 and the exposure processing by the exposure device 800.

In the above-mentioned substrate processing apparatus 100, the substrate transport device 500 according to any of the first to fourth embodiments is provided. Thus, because a period of time required for determination of the position of the substrate W can be reduced, a period of time required for transporting the substrate is shortened, and the throughput of the substrate processing is improved. Further, the substrate W is transported among the plurality of processing units PU, TU. Thus, in each of the processing units PU, TU, an occurrence of processing defect caused by a deviation of the position of the substrate W is prevented, and the processing accuracy of the substrate W is improved.

### 6. Other Embodiments

(1) While the reflective photo detectors SA1 to SA5 are fiber sensors and emit linear light to the detection regions df1 to df5 in the substrate transport device 500 according to each of the first to fourth embodiments, the present invention is not limited to this. In each of the reflective photo detectors SA1 to SA5, the light receiving surface that receives light reflected from the substrate W may be formed linearly. Therefore, the reflective photo detectors SA1 to SA5 may be configured to emit circular, oval or rectangular light upwardly.

(2) While the five reflective photo detectors SA1 to SA5 are used to determine the position of the substrate W in each of the hands H1, H2 in the substrate transport device 500 according to each of the first to fourth embodiments, the present invention is not limited to this.

For example, in a case in which the design radius of the substrate W subject to position determination is known, only four reflective photo detectors SA1 to SA4 for determining the position of the substrate W may be provided in each of the hands H1, H2. In this case, the imaginary circle (the imaginary circle cr4 in the present example) having a radius that coincides with a design radius or is the closest to the design radius out of the four imaginary circles cr1 to cr4 generated with use of the reflective photo detectors SA1 to SA4 is selected. Therefore, it is possible to determine the position of the substrate W in each of the hands H1, H2 based on a selected imaginary circle.

Further, in a case in which a notch is not formed in the substrate W subject to position determination, for example, only three reflective photo detectors SA1 to SA3 for determining the position of the substrate W may be provided in each of the hands H1, H2. In this case, the position of the substrate W in each of the hands H1, H2 can be determined based on an imaginary circle passing through the positions of three portions p1 to p3 of the substrate W calculated by the three reflective photo detectors SA1 to SA3.

Further, in a case in which a notch is not formed in the substrate W subject to position determination and a design radius of the substrate W is known, for example, only two reflective photo detectors SA1, SA2 for determining the position of the substrate W may be provided in each of the hands H1, H2. In this case, the position of the substrate W in each of the hands H1, H2 can be determined based on two imaginary circles passing through the positions of the two portions p1, p2 of the substrate W calculated by the two reflective photo detectors SA1, SA2 and having the design radius, and the estimated positional relationship between the substrate W and each of the reflective photo detectors SA1, SA2.

(3) While the reflective photo detectors SA1 to SA5 are arranged on each of the hands H1, H2 such that the light transmission surfaces ss are in parallel with the advancing retreating direction AB in the substrate transport device 500 according to each of the first to fourth embodiments, the present invention is not limited to this. The reflective photo detectors SA1 to SA5 may be formed such that at least part of the light transmission surfaces ss of the reflective photo detectors SA1 to SA5 extends in a direction different from the direction in which other light transmission surfaces ss extend.

(4) While the reflective photo detector SB1 basically has the same configuration as that of each of the reflective photo detectors SA1 to SA5 in the substrate transport device 500 according to each of the second and third embodiments, the present invention is not limited to this. The reflective photo detector SB1 may have the configuration with which the reflectance of the substrate W with respect to the light emitted from each of the reflective photo detectors SA1 to SA5 can be obtained, and may have the configuration different from that of each of the reflective photo detectors SA1 to SA5.

(5) While the reflective photo detectors SC1 to SC4 basically have the same configuration as that of each of the reflective photo detectors SA1 to SA5 in the substrate transport device 500 according to the third embodiment, the present invention is not limited to this. The reflective photo detectors SC1 to SC4 may have the configuration with which the height of each of the plurality of portions p1 to p5 of the substrate W with respect to the height of the inner portion p10 calculated with the use of each of the plurality of reflective photo detectors SA1 to SA5 can be obtained. Therefore, in the third embodiment, a plurality of height sensors for calculating the height relationship between the plurality of portions p1 to p5 and the inner portion p10 of the substrate W may be provided instead of the reflective photo detectors SC1 to SC4.

### 7. Correspondences Between Constituent Elements in Claims and Parts in Preferred Embodiments

In the following paragraphs, non-limiting examples of correspondences between various elements recited in the claims below and those described above with respect to various preferred embodiments of the present disclosure are explained. In the above-mentioned embodiment, the substrate transport device 500 is an example of a substrate transport device, the hands H1, H2 are an example of a holder, the light transmission surface ss is an example of a light receiving surface, the plurality of reflective photo detectors SA1 to SA5 are an example of a plurality of reflective photo detectors, the portion position calculator 51 is an example of a portion position calculator and the substrate position determiner 53 is an example of a substrate position determiner.

Further, the detection regions df1 to df5 of the reflective photo detectors SA1 to SA5 are examples of a strip-shaped detection region, the advancing retreating direction AB is an example of one direction, the reflective photo detectors SA1, SA2 are examples of a first reflective photo detector, the reflective photo detectors SA3, SA4, SA5 are examples of a second reflective photo detector and the light amount position information storage 81 is an example of a storage.

Further, the reflective photo detector SB1 is an example of a light receiving amount measurer, the light amount position information generator 82 is an example of a light amount position information generator, the plurality of suction portions sm are an example of a plurality of suction portions, the plurality of reflective photo detectors SC1 to SC4 are examples of a height detector and the portion position corrector 83 is an example of a corrector.

Further, the configuration including the vertical direction driving motor 511, the horizontal direction driving motor 513, the rotation direction driving motor 515, the upper-hand advancing retreating driving motor 525, the lower-hand advancing retreating driving motor 527, the movement member 510 and the rotation member 520 is an example of a mover, the receiving position is an example of a first position, the placing position is an example of a second position and the movement controller 58 is an example of a movement controller.

As each of constituent elements recited in the claims, various other elements having configurations or functions described in the claims can be also used.

While preferred embodiments of the present disclosure have been described above, it is to be understood that variations and modifications will be apparent to those skilled in the art without departing the scope and spirit of the present disclosure. The scope of the present disclosure, therefore, is to be determined solely by the following claims.

I/We claim:

1. A substrate transport device that transports a substrate, comprising:
a holder configured to be capable of holding the substrate;
a plurality of reflective photo detectors that have linear light receiving surfaces, are provided at the holder, respectively emit light toward an outer periphery of the substrate arranged on the holder, respectively receive light reflected from the substrate using the light receiving surfaces and output signals representing light receiving amounts;
a portion position calculator that calculates respective positions of a plurality of portions of an outer peripheral end of the substrate in the holder in regard to the substrate arranged on the holder based on output signals of the plurality of reflective photo detectors; and
a position determiner that determines a position of the substrate with respect to the holder based on positions of the plurality of portions of the substrate calculated by the portion position calculator.

2. The substrate transport device according to claim 1, wherein
the plurality of reflective photo detectors respectively have strip-shaped detection regions extending upwardly from the light receiving surfaces, and
the plurality of portions are intersections between the detection regions of the plurality of reflective photo detectors and the outer peripheral end of the substrate arranged on the holder in a plan view.

3. The substrate transport device according to claim 1, wherein
the plurality of reflective photo detectors include first and second reflective photo detectors provided at the holder such that the light receiving surfaces do not overlap with each other in one direction.

4. The substrate transport device according to claim 1, further comprising a storage that stores light amount position information representing a predetermined relationship between an amount of light received by the plurality of reflective photo detectors and positions of the plurality of portions of the substrate in the holder, wherein
the portion position calculator calculates respective positions of the plurality of portions of the substrate in the holder based on the light amount position information stored in the storage in addition to output signals of the plurality of reflective photo detectors.

5. The substrate transport device according to claim 1, further comprising:
a light receiving amount measurer that is provided at the holder, emits light toward an inner portion located inwardly of the outer periphery of the substrate, receives light reflected from the substrate and outputs a signal indicating a light receiving amount; and
a light amount position information generator that generates light amount position information representing a relationship between an amount of light received by the plurality of reflective photo detectors and positions of the plurality of portions of the substrate in the holder based on an output signal of the light receiving amount measurer, wherein
the portion position calculator calculates respective positions of the plurality of portions of the substrate in the holder based on the light amount position information generated by the light amount position information generator in addition to output signals of the plurality of reflective photo detectors.

6. The substrate transport device according to claim 5, wherein
the holder further has a plurality of suction portions that hold a lower surface of the substrate by suction, and
a distance between the light receiving amount measurer and one suction portion out of the plurality of suction portions is smaller than a distance between each of the plurality of reflective photo detectors and the one suction portion.

7. The substrate transport device according to claim 1, further comprising:
a height detector that detects heights of the plurality of portions of the substrate in the holder; and
a corrector that corrects respective positions of the plurality of portions of the substrate calculated by the portion position calculator based on heights of the plurality of portions of the substrate detected by the height detector, wherein
the position determiner determines a position of the substrate with respect to the holder based on positions of the plurality of portions of the substrate after the positions are corrected by the corrector.

8. The substrate transport device according to claim 1, further comprising a photo detector controller that controls the plurality of reflective photo detectors, wherein
the light detector controller is configured to be workable in
a first control mode in which the light detector controller controls the plurality of reflective photo detectors with the substrate held by the holder, and
a second control mode in which the light detector controller controls the plurality of reflective photo detectors with the substrate not held by the holder and the holder arranged at a position below the substrate supported by a supporter.

9. The substrate transport device according to claim 1, further comprising:
a mover that moves the holder; and
a movement controller that controls the mover based on a result of determination by the position determiner such that the substrate held by the holder is transported from a predetermined first position to a predetermined second position.

10. A substrate transport method of transporting a substrate including:
arranging a substrate on a holder configured to be capable of holding the substrate;
using a plurality of reflective photo detectors that have the linear light receiving surfaces and are provided at the holder, emitting light toward an outer periphery of the substrate arranged on the holder, receiving light reflected from the substrate and outputting signals respectively representing light receiving amounts from the plurality of reflective photo detectors;
calculating respective positions of a plurality of portions of an outer peripheral end of the substrate in the holder in regard to the substrate arranged on the holder based on output signals of the plurality of reflective photo detectors; and
determining a position of the substrate with respect to the holder based on positions of the plurality of portions of the substrate calculated in the calculating.

11. The substrate transport method according to claim 10, wherein
the plurality of reflective photo detectors respectively have strip-shaped detection regions extending upwardly from the holder, and
the plurality of portions are intersections between detection regions of the plurality of reflective photo detectors and the outer peripheral end of the substrate arranged on the holder in a plan view.

12. The substrate transport method according to claim 10, wherein
the plurality of reflective photo detectors include first and second reflective photo detectors provided at the holder such that the light receiving surfaces do not overlap with each other in one direction.

13. The substrate transport method according to claim 10, further including storing light amount position information representing a predetermined relationship between an amount of light received by the plurality of reflective photo detectors and positions of the plurality of portions of the substrate in the holder, wherein
the calculating includes calculating respective positions of the plurality of portions of the substrate in the holder based on the light amount position information stored in the storing in addition to output signals of the plurality of reflective photo detectors.

14. The substrate transport method according to claim 10, further including:
causing a light receiving amount measurer to output a signal indicating a light receiving amount by emitting light toward an inner portion located inwardly of the outer periphery of the substrate arranged on the holder using the light receiving amount measurer provided at the holder and receiving light reflected from the substrate; and
generating light amount position information representing a relationship between an amount of light received by the plurality of reflective photo detectors and positions of the plurality of portions of the substrate in the holder based on an output signal of the light receiving amount measurer, wherein
the calculating includes calculating respective positions of the plurality of portions of the substrate in the holder based on the light amount position information generated in the generating in addition to output signals of the plurality of reflective photo detectors.

15. The substrate transport method according to claim 14, wherein
the arranging a substrate on a holder includes holding a lower surface of the substrate by suction using a plurality of suction portions of the holder, and
a distance between the light receiving amount measurer and one suction portion out of the plurality of suction portions is smaller than a distance between each of the plurality of reflective photo detectors and the one suction portion.

16. The substrate transport method according to claim 10, further including:
detecting heights of the plurality of portions of the substrate in the holder; and
correcting respective positions of the plurality of portions of the substrate calculated in the calculating based on heights of the plurality of portions of the substrate detected in the detecting heights, wherein
the determining a position of a substrate includes determining a position of the substrate with respect to the holder based on positions of the plurality of portions of the substrate after the positions are corrected in the correcting.

17. The substrate transport method according to claim 10, wherein
the causing a light receiving amount measurer to output a signal indicating a light receiving amount includes emitting light toward the outer periphery of the substrate held by the holder and emitting light toward the outer periphery of the substrate with the substrate not held by the holder and the holder arranged at a position below the substrate supported by a supporter.

18. The substrate transport method according to claim 10, further including moving the holder such that the substrate held by the holder is transported from a predetermined first position to a predetermined second position based on a result of determination in the determining a position of a substrate.
